(19) United States
(12) Patent Application Publication
(10) Pub. No.: US 2015/0177191 A1
(43) Pub. Date: Jun. 25, 2015

(54) HIGH RESOLUTION EDDY CURRENT ARRAY PROBE

(71) Applicant: EDDYFI NDT INC., Québec (CA)

(72) Inventors: Florian Hardy, Saint-Augustin-de-Desmaures (CA); Marc Grenier, Quebec (CA)

(21) Appl. No.: 14/409,020

(22) PCT Filed: Jun. 20, 2013
(86) PCT No.: PCT/IB2013/055086

§ 371 Date: Dec. 18, 2014

Related U.S. Application Data
(60) Provisional application No. 61/662,777, filed on Jun. 21, 2012.

(51) Int. Cl. G01N 27/90; G01R 33/09; G01R 33/07

(52) U.S. Cl. CPC G01N 27/9033; G01R 33/07; G01R 33/09; G01N 27/904

(57) ABSTRACT

An eddy current array probe comprising a probe body adapted to be displaced along a scan direction; a plurality of coils arranged in a linear configuration on the surface of the probe body, the coils being adapted to be operated in one mode among a transmit mode, an inactive mode and a receive mode at each of a plurality of time-spaced instances, at least two adjacent coils of the plurality being adapted to be operated in the inactive mode between a coil adapted to be in transmit mode and a coil adapted to be in receive mode in the linear configuration at each of the time-spaced instances; at least one conductor extending from the probe body; each coil of the plurality being connected to one of the at least one conductor and a common return path. In one embodiment, the coils have an elongated shape.

### TECHNICAL FIELD

The invention relates to eddy current testing and more particularly to an eddy current testing probe using an array of coils in transmit-receive mode.

### BACKGROUND OF THE ART

Eddy Current Technology (ECT) is based on the physics phenomenon of electromagnetic induction: an alternating current flowing through a coil instantly generates an oscillating magnetic field. If the coil and its magnetic field approach an electrically conductive material, a circular flow of electrons, known as eddy current, is induced in this electrically conductive material. In turn, this eddy current generates its own magnetic field, which will interact through mutual inductance with the coil and its magnetic field. Defects in the material (cracks, pitting, wall loss, or other discontinuities) disrupt the flow of the eddy current and its magnetic field, thus also modifying the electrical impedance of the coil.

Some basic ECT probes have a single coil which is used both as a driver coil to emit the magnetic field and as a receiver coil to read out the electrical impedance.

Some other basic ECT probes have an emit coil which is used to emit the magnetic field to induce eddy current in an electrically conductive material. In turn, this eddy current generates its own magnetic field. A receive coil is used to collect the magnetic field present close to the induced eddy current in the electrically conductive material. The receive coil converts the received magnetic field to a voltage. Defects in the material disrupt the flow of the eddy current and its magnetic field, thus also modifying the electrical voltage produced by the receive coil.

Eddy current is appropriate for inspection of non-ferrous tubing. It can detect and size defects affecting tubing such as steam erosion, baffle cuts, pitting, and cracking. Eddy current is especially good for detection of defects under support plates.

Eddy current is also appropriate for various electrically conductive surface inspections. It can detect and size defects such as corrosion and cracks. It can measure the material conductivity and thickness of coating.

In a basic eddy current tube inspection probe, two coils are excited with an alternating electrical current. The coils produce a magnetic field that induces eddy currents along the circumference of the tube. If a defect disturbs the eddy current flow, the impedance of the coil will change and be measured by the acquisition unit. Using two frequencies, it is possible to reduce the support plate disturbance and only keep the relevant flaw information. Using multi-frequencies and phase signal permit defect discrimination against foreign objects (loose bolt), iron or copper deposit.

Eddy Current Array (ECA) probes use a number of individual coils grouped together in one assembly. Some coils are used as transmit coils and some coils are used as receive coils. The transmit coils are connected to an AC signal and convert it into a magnetic field which induces eddy current in the inspected part located close to the driver coil. The receiver coils convert the received magnetic fields and transform them into an AC signal. The AC signal of each receive coil can be read and becomes collected data from the probe. The impedance of each transmit coil can be read and becomes collected data from the probe. These transmit and receive coils are used in a multiplexed sequence to eliminate interference (mutual inductance) between coils in close proximity. Coils work together to scan a wider inspection area than conventional single coil probes. To optimize performance, array probes can be made flexible or shaped to match the geometry of the part to inspect. Data from ECA probes, which can be encoded, is typically transmitted to a software module for graphical display (C-scans), record keeping, and/or reporting.

ECA probes can be used in lieu of magnetic particle, liquid penetrant and single-coil ECT probes to significantly reduce inspection time, improve flaw detection, and provide full inspection records.

Array probes can be manufactured with a wide variety of coil sizes and types based on the properties of the defect to find (size, orientation, depth, type, etc.), on material properties, and on surface properties. Furthermore, the person skilled in the art selects the coil shape, diameter, impedance, mode of operation (absolute, differential, transmit-receive, transfo-differential, etc.), and operating frequencies.

The eddy current testing probe using an array of coils in transmit-receive absolute mode is very sensitive to parasitic lift-off variation signal. The probability of detection of flaws and the accuracy of the flaw characterization are reduced if the lift-off varies while the test part is inspected with the probe. Furthermore, if the coil size is too small or too large, it will not be sensitive enough to small flaws.

Most of the time, it is not possible to combine the optimized transmit to receive coil distance, the optimal circular coil diameter and reach a high coil density in an array of coils without having to distribute the array of coil on several adjacent rows. The resulting probe design is either a low resolution design compromised with reduced performances or a good resolution probe with several rows of coils. The additional rows of coil necessitate an encoding mechanism to realign the signal from each row to build a single image and elongate the probe length which can create mechanical compatibility issues in several applications.

### SUMMARY

According to one broad aspect of the present invention, there is provided an eddy current array probe. The array probe comprises a probe body having a surface, the probe body being adapted to be displaced along a scan direction; a plurality of coils arranged in a linear configuration on the surface, the coils being adapted to be operated in one mode among a transmit mode, an inactive mode and a receive mode at each of a plurality of time-spaced instances, at least two adjacent coils of the plurality being adapted to be operated in the inactive mode between a coil adapted to be in transmit mode and a coil adapted to be in receive mode in the linear configuration at each of the time-spaced instances; at least one conductor extending from the probe body; each coil of the plurality being connected to one of the at least one conductor and a common return path.

In one embodiment, the array probe further comprises a conduit attached to the probe body, the at least one conductor extending within the conduit.

In one embodiment, the coils have an elongated shape.

In one embodiment, the elongated shape is an oval shape.

In one embodiment, a longitudinal dimension of the elongated shape is orthogonal to a longitudinal dimension of the linear configuration.

In one embodiment, at least two adjacent coils of the plurality are adapted to be operated in the transmit mode in the linear configuration in at least one time-spaced instance of the plurality of time-spaced instances.

In one embodiment, the probe body is cylindrical, wherein the linear configuration is a ring-like circumferential configuration on the surface of the probe body, wherein the probe body has a hollow core, wherein the at least one conductor is inserted in the hollow core of the probe body.

In one embodiment, the linear configuration includes at least two rows of the coils, the longitudinal dimension of each of the rows being parallel, coils of the rows being in one of an alignment and an offset with coils of an adjacent one of the rows.

In one embodiment, the array probe further comprises a multiplexer in the probe body, the multiplexer being connected between one of the at least one conductor and at least two coils of the plurality of coils.

In one embodiment, the multiplexer including a multiplexer memory, the multiplexer memory storing a sequence for triggering the coils to be operated in one of the mode at each of the plurality of time-spaced instances.

In one embodiment, the array probe further comprises a plurality of sensors arranged in a sensor linear configuration, the coils being provided on at least one coil row and the sensors being provided on at least one sensor row, the sensors being one of Hall effect sensors and magnetoresistive sensors, the sensor row being one of adjacent to and superposed on the coil row.

In one embodiment, the array probe further comprises an amplifier in the probe body, the amplifier being adapted to amplify a signal from the coil operated in the receive mode.

According to another broad aspect of the present invention, there is provided an method for generating inspection data about an electrically conductive material to be tested using an eddy current array probe. The method comprises providing an eddy current array probe in interaction with the electrically conductive material; retrieving a sequence of current modes for each of the time-spaced instances, for each coil of the plurality of coils, the current mode being chosen among the transmit mode, the inactive mode and the receive mode; triggering each coil of the plurality of coils to be operated in the mode using the sequence, the at least one conductor and a power source, at each of the time-spaced instances; receiving a signal from the coils in the receive mode using the at least one conductor at each of the time-spaced instances; storing inspection data using the signal at each of the time-spaced instances;

displacing the eddy current array probe in a scan direction; repeating the steps of triggering, receiving, storing and displacing; wherein the sequence of current modes ensures at least two adjacent coils of the plurality are triggered to be operated in the inactive mode between a coil triggered to be operated in transmit mode and a coil triggered to be operated in receive mode in the linear configuration at each of the time-spaced instances.

In one embodiment, the sequence includes at least one instance in which at least two adjacent coils of the plurality are triggered to be in the transmit mode in the linear configuration.

In one embodiment, the method further comprises multiplexing commands for the triggering.

In one embodiment, the method further comprises displaying the inspection data.

### BRIEF DESCRIPTION OF THE DRAWINGS

Having thus generally described the nature of the invention, reference will now be made to the accompanying drawings, showing by way of illustration example embodiments thereof and in which:

FIG. 1 is an example probe shown on part to be inspected with a plurality of flaws;

FIG. 2 is an example high-density coil;

FIG. 3 is a block diagram of main components of an example system for use with the probe of FIG. 1;

FIG. 4 includes FIG. 4A to FIG. 40 which show 15 timeslots of an example time-multiplexed transmit/receive sequence in double-driver mode with two rows of 18 coils;

FIG. 5 is a legend for FIG. 4 to FIG. 17;

FIG. 6 shows example connections of the coils with conductors via multiplexers to reduce a number of conductors required to control the coils for the sequence of FIG. 4, the conductors being multiplexed to bring the AC signal for the transmit coils;

FIG. 7 shows example connections of the coils with conductors via multiplexers to reduce a number of conductors required to control the coils for the sequence of FIG. 4, the conductors being multiplexed to bring the receive coil signals to the electronic equipment;

FIG. 8 includes FIG. 8A to FIG. 8M which show 13 timeslots of a time-multiplexed transmit/receive sequence for an example probe having two rows of 24 coils in single-driver mode;

FIG. 9 shows example connections of the coils with conductors via multiplexers to reduce a number of conductors required to control the coils for the sequence of FIG. 8;

FIG. 10 includes FIG. 10A to FIG. 10J which show 10 timeslots of an alternative time-multiplexed excitation/receive sequence for the example probe having two rows of 24 coils in single-driver mode of FIG. 8;

FIG. 11 shows example connections of the coils with conductors via multiplexers to reduce a number of conductors required to control the coils for the sequence of FIG. 10;

FIG. 12 includes FIG. 12A to FIG. 121 which show 9 timeslots of a time-multiplexed transmit/receive sequence for an example probe having two rows of 18 coils in single-driver mode;

FIG. 13 includes FIG. 13A to 13I which show 9 timeslots of a time-multiplexed transmit/receive sequence for an example probe with an array of 18 coils on one row;

FIG. 14 includes FIG. 14A to FIG. 14J which show 10 timeslots of a time-multiplexed transmit/receive sequence for an example probe having two rows of 16 circular coils and one row of 24 high density coils in single-driver mode;

FIG. 15 shows example connections of the coils with conductors via multiplexers to reduce a number of conductors required to control the coils for the sequence of FIG. 14;

FIG. 16 shows an example probe for tubing inspection having basic eddy current tube inspection coils and a row of high density transmit coils with 2 rows of magneto-resistive or Hall effect sensors;

FIG. 17 includes FIG. 17A to FIG. 17I which show 9 timeslots of a time-multiplexed excitation/receive sequence for the example probe shown in FIG. 16; and

FIG. 18 is a flow chart of example main steps for a method of obtaining inspection data.

It will be noted that throughout the appended drawings, like features are identified by like reference numerals.

### DETAILED DESCRIPTION

The eddy current array probe comprises a probe body having a surface. The probe body is adapted to be displaced along a scan direction. The array probe also includes a plurality of coils arranged in a linear configuration on the surface and at least one conductor extending from the probe body. Each coil is connected to a conductor and a common return path.

The coils are adapted to be operated in one mode among a transmit mode, an inactive mode and a receive mode at each of a plurality of time-spaced instances. At least two adjacent coils of the plurality are adapted to be operated in the inactive mode between a coil adapted to be in transmit mode and a coil adapted to be in receive mode in the linear configuration.

In one embodiment, the coils have an elongated shape and are referred to as high density coils. The longitudinal dimension of the elongated shape can be at an angle to a longitudinal dimension of the linear configuration. In one embodiment, that elongated shape is an oval shape. In an alternative embodiment, the coils are circular.

The probability of detection of the flaws is linked to the ratio between the signal amplitude of the flaw and the lift-off signal amplitude. There is an optimal distance between the transmit and receive coils where this ratio is maximized. With prior art circular coils, adjacent coils are used for transmit and receive or 1 unused coil is used between the transmit and receive coils.

It is desirable to increase the transversal coil density to measure the length of a transversal flaw with increased accuracy and/or to discriminate between closely located parallel longitudinal flaws. A higher transversal coil density can be achieved with circular coils each having a smaller diameter than used in prior art array probes. However, when one uses smaller diameter circular coils with one inactive coil between transmit and receive coils, it increases the parasitic signal coming from lift-off variation.

Proposed herein is a coil density in which there are two or more inactive coils between transmit and receive coils. Increasing the distance between transmit and receive coils avoids the increase of the parasitic signal. High transversal resolution can therefore be achieved with prior art circular coils. Unfortunately, the flaw sensibility (or flaw signal) is reduced since the transmit and receive coils are provided further apart. The person skilled in the art will determine if the loss in flaw sensibility or the increased accuracy is prevalent for the embodiment to be designed.

Proposed herein is a solution to increase the flaw sensibility in a high transversal resolution embodiment. A coil having an elongated shape can be used. The larger footprint of the elongated coil shape can transfer more energy to the part and improve the flaw signal amplitude, thus improving the overall signal to noise ratio. By using elongated coils with an appropriate ratio between length and width, it is possible to maintain the optimal transversal distance and increase the resolution.

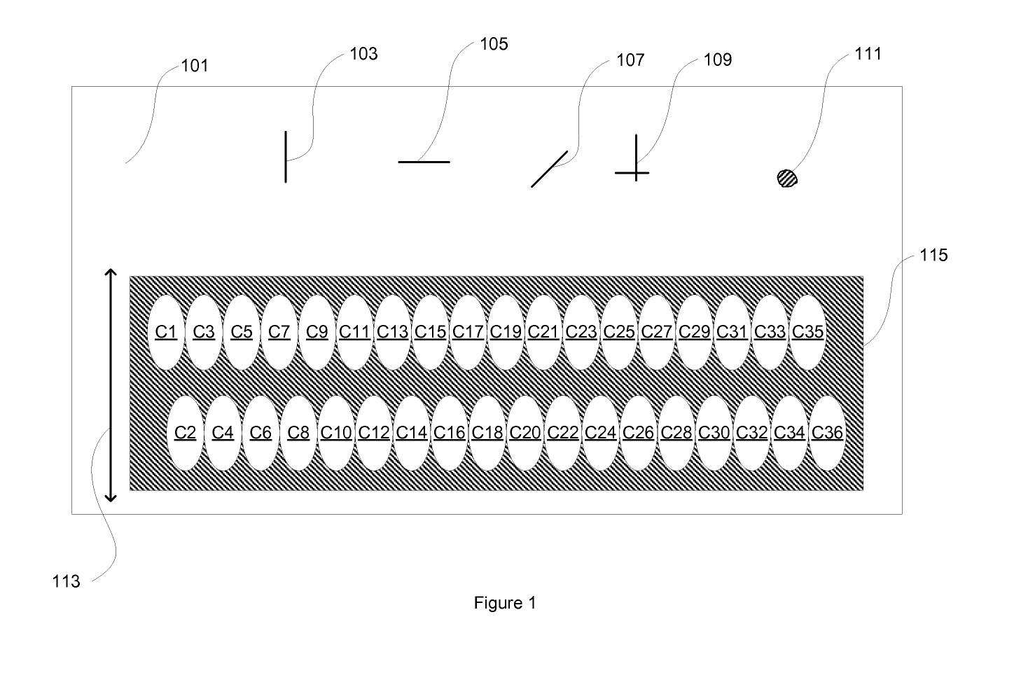

FIG. 1 illustrates an example eddy current array probe. The example array probe 115 includes two rows of 18 elongated coils each. In the example shown in FIG. 1, the array probe is shown to be flat with the coils being provided on a single plane. The probe is displaced in the scan direction 113 shown in FIG. 1. The scan direction is perpendicular to the longitudinal dimension of the rows.

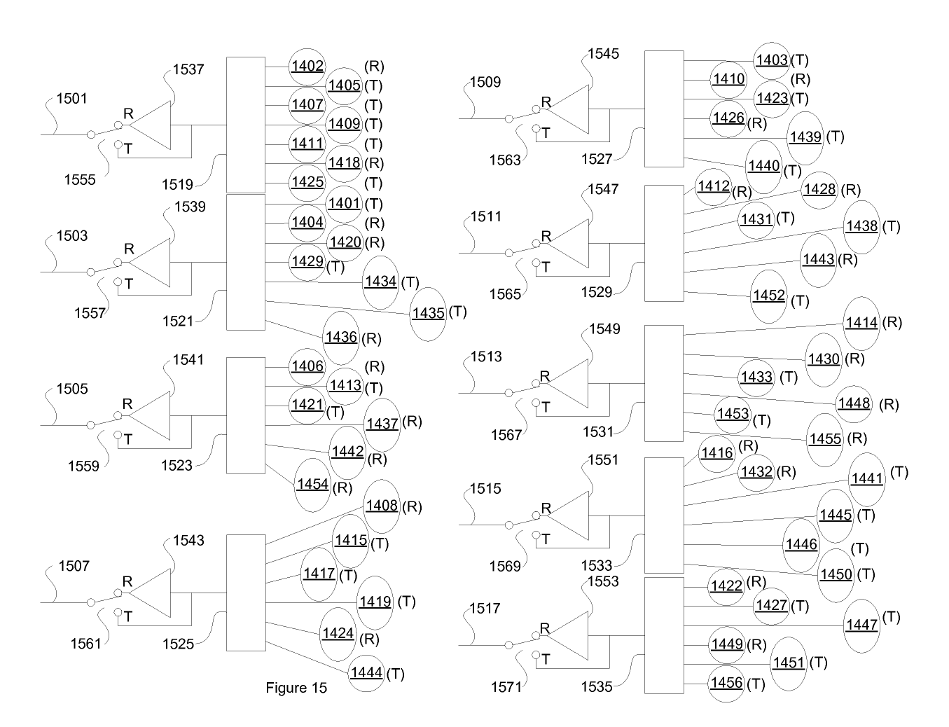

As will be readily understood, depending on the shape of the part to be tested and/or inspected, it may be advantageous to provide the coils in a ring-like arrangement on the circumference of a cylindrical probe body. This would be useful for inspecting tubes, for example. Then, coil C1 becomes adjacent to coil C35 and coil C2 becomes adjacent to coil C36. Because the coils then cover a 360° range, there is no need to rotate the probe body during scanning. FIG. 15 shows such a ring-like arrangement of coils on a probe body for a different configuration.

The total number of coils, the shape of the coils and the number of coils per row will be chosen by the person skilled in the art depending on the surface of the part to be inspected and the resolution required.

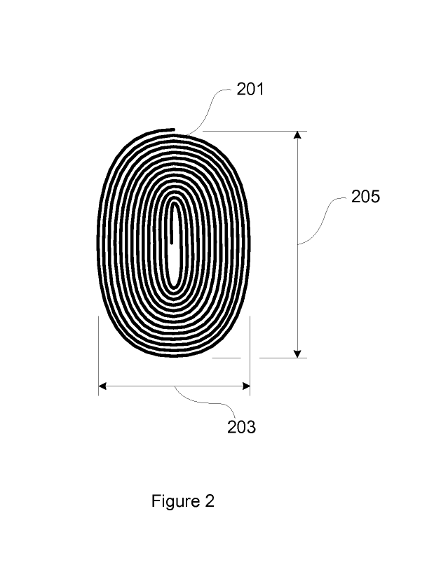

Each coil can be built using an insulated wire 201 which is winded on itself for many turns as illustrated in FIG. 2. Even though a single layer of windings is shown on FIG. 2 for simplicity, it will be readily understood that multiple layers of windings of the wire 201 can form the coil. The coil therefore has a thickness which can be greater than the diameter of the wire and will typically be the thickness of a plurality of layers of windings. Alternatively the coil can be built using an electrically conductive trace having a shape similar to than illustrated in FIG. 1. The conductive trace can be provided on a non-electrically conductive substrate. One or many layers of conductive traces may be used which can be separated by non-electrically conductive material.

The shape of an elongated coil is different than the usual circular or spherical shape. The elongated coil is referred to as a high density coil. The aspect ratio of the high density coil is different than 1. The coil width 203 is smaller than the coil length 205. The coil therefore has an elongated shape. The narrowed width of the coil allows a higher coil density on each row of coils of the probe. The extended length dimension of the coil compensates for the narrowed width dimension to keep the overall surface of the coil somewhat equivalent to a circular shaped coil. The density of coils, namely the quantity of coils which can be provided in one row of a fixed length without touching, is increased in the longitudinal dimension of the rows. Example coil shapes which have an aspect ratio different than 1 include cylindrical, rectangular, oblong, obround, ellipsoid, elliptical, egg-shaped, etc.

The person skilled in the art will select a shape which allows a high transversal density will being reproducible with a somehow constant result to allow manufacturing of a plurality of coils for the probe. Furthermore, the person skilled in the art will determine the coil shape aspect ratio, coil overall size and coil quantity to get the best performances in terms of defect signal amplitude, lift-off signal perturbation and transversal resolution.

In one example embodiment, a standard circular coil has a diameter of 2.5 mm and a thickness of 0.5 mm with an insulated wire 201 size of 46-47 in the American Wire Gauge (AWG) system. A higher density non-circular coil could be oval shaped as shown in FIG. 2. The oval shaped example coil could have a coil width 203 of 1.5 mm and a coil length 205 of 3.5 mm and a thickness of 0.5 mm. It would use a similar coil perimeter and area but its shape would be compressed in one dimension to allow a higher density of coils to be provided on a single row of the same length.

One end of the insulated wire 201 is connected, typically by soldering, with the conductor. The other end of the coil wire is typically connected to the common electrical point or the current common return path. In case of a cylindrical probe body with a hollow core, the wire ends can be inserted into the probe body and the connections can be done inside the hollow core. The coils can be soldered on a printed circuit board, for example a flexible printed circuit board and the conductors can be connected to the printed circuit board.

In one embodiment, the coils can be provided in a coil holder with a properly shaped receiving area for each coil. This coil holder can then be received in a recessed area of the probe surface. In this embodiment, the surface of the probe is substantially flat even when provided with the coils. Alternatively, the coils can be provided in recessed sections of the probe surface directly, without using a coil holder.

In one embodiment, a protective sleeve or casing is provided over the probe surface to protect the coils. This protective sleeve can be made of a material which is not electrically conductive or which has a low electrical conductivity. It can be made of plastic which is not electrically conductive but which is somewhat fragile and can be inappropriate in certain applications, such as when the surface of the part to be inspected is rough and could break the plastic sleeve. It can alternatively be made of a very thin layer of Titanium which has a low conductivity. The layer of Titanium will cause a small loss in the amplitude of the signal read out by the receiver coils but this loss can be considered to be negligible in some applications.

Referring back to FIG. 1, in use, the probe is positioned over the part under test 101. The scan direction 113 is perpendicular to the longitudinal rows of coils. The part under test 101 has flaws, including longitudinal flaw 103 which is a thin flaw oriented in the same direction as the scan direction, transversal flaw 105 which is a thin flaw oriented perpendicularly to the scan direction and volumetric flaws including diagonal thin flaw 107, thin flaw 109 extending in both the transversal and longitudinal directions, and a three dimensional flaw 111.

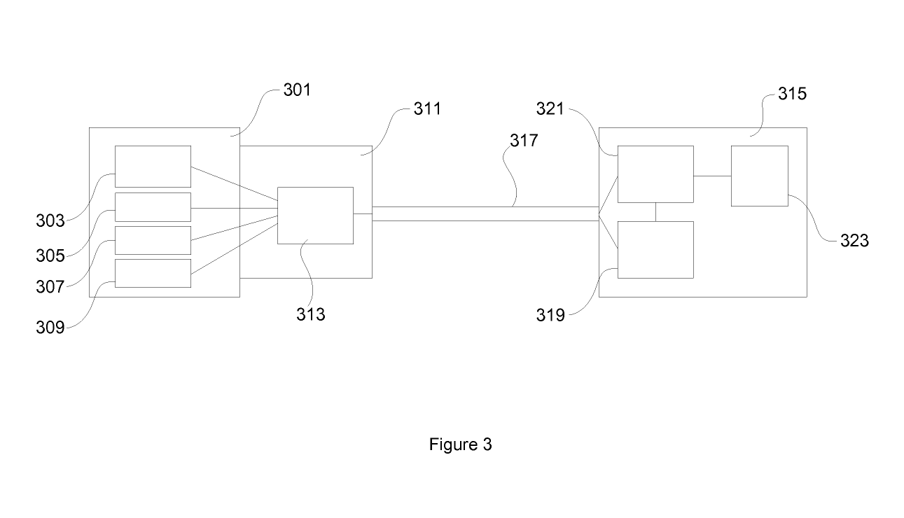

FIG. 3 shows a block diagram of the main components of an example combined eddy current equipment 301 with the probe of FIG. 1. The Time multiplexed AC source 303 is used to generate the waveform voltage to apply to the coils to be excited. The Receiver circuits 305 are used to read the time multiplexed voltages received from the probe. The DC power 307 supplies the required electric power to the probe electronic circuit. The Step control line circuit 309 provides the required control line signals to step from one timeslot to the next one. In the probe connector 311, some signal conditioning circuits 313 may be provided to ensure the input/output signals of the eddy current equipment 301 are compatible with the input/output signals of the probe head 315. The probe cable 317 contains all conductors linking the probe head 315 to the probe connector 311. The Step control circuit 319 interprets the signals received from the Step control line circuit 309 to generate each control line required by the multiplexer circuit to change the multiplexer selections at each step (timeslot). In this example, the Coil multiplexer 321 and the Step control circuit 319 are located in the probe head 315 to reduce the number of conductors in the probe cable 317. Those circuits may be located in the eddy current equipment 301, in the Probe connector 311 or in a separate Multiplexer unit. The Coil set 323 includes all coils used for the eddy current measurement, which can include High density coils.

The sequence of transmit-receive modes for each coil can be controlled by the test equipment to which the probe is connected via the conductors. It can be hardcoded in a memory of the test equipment or partly to fully customizable depending on the design of the test equipment. Alternatively, the sequence could be hardcoded in a memory in the probe if a sufficiently able circuit is provided in the probe.

As will be readily understood, it may be necessary to provide power to the probe.

As will be readily understood by one skilled in the art, selecting an appropriate transmit-receive coil distance, an appropriate coil size and a high density coil with appropriate aspect ratio will allow to attain a high signal quality and to increase the probability of detection of flaws and improve the accuracy of the flaw characterization.

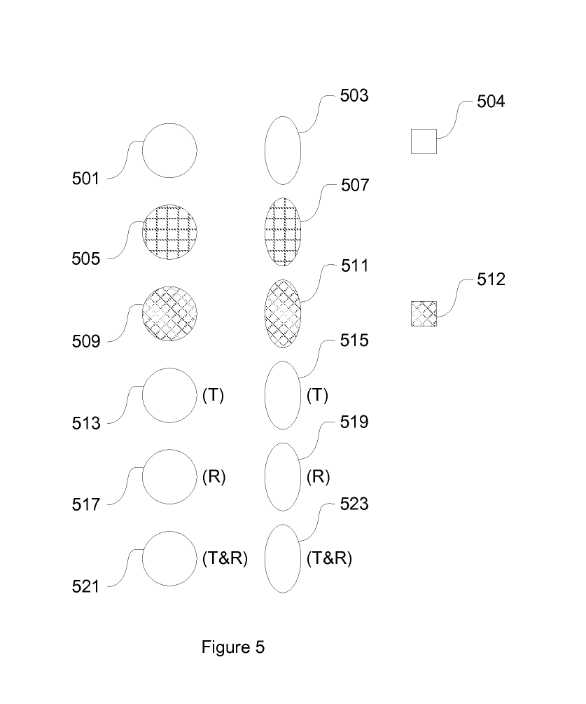

FIG. 5 provides a legend of the drawing marks used to identify the mode in which the sensors (coils or others) are operated in each timeslot. The legend is as follows: unused circular shape coil 501, unused elongated shape coil 503, unused electromagnetic receive other than a coil 504, transmit circular shape coil 505, transmit elongated shape coil 507, receive circular shape coil 509, receive elongated shape coil 511 and electromagnetic receive other than a coil 512, circular coil used as transmit coil during at least one timeslot but not used as receive coil in any timeslot 513, elongated coil used as transmit coil during at least one timeslot but not used as receive coil in any timeslot 515, circular coil used as receive coil during at least one timeslot but not used as transmit coil in any timeslot 517, elongated coil used as receive coil during at least one timeslot but not used as transmit coil in any timeslot 519, circular coil used as receive coil during at least one timeslot and use as transmit coil during at least one timeslot 521 and elongated coil used as receive coil during at least one timeslot and used as transmit coil during at least one timeslot 523.

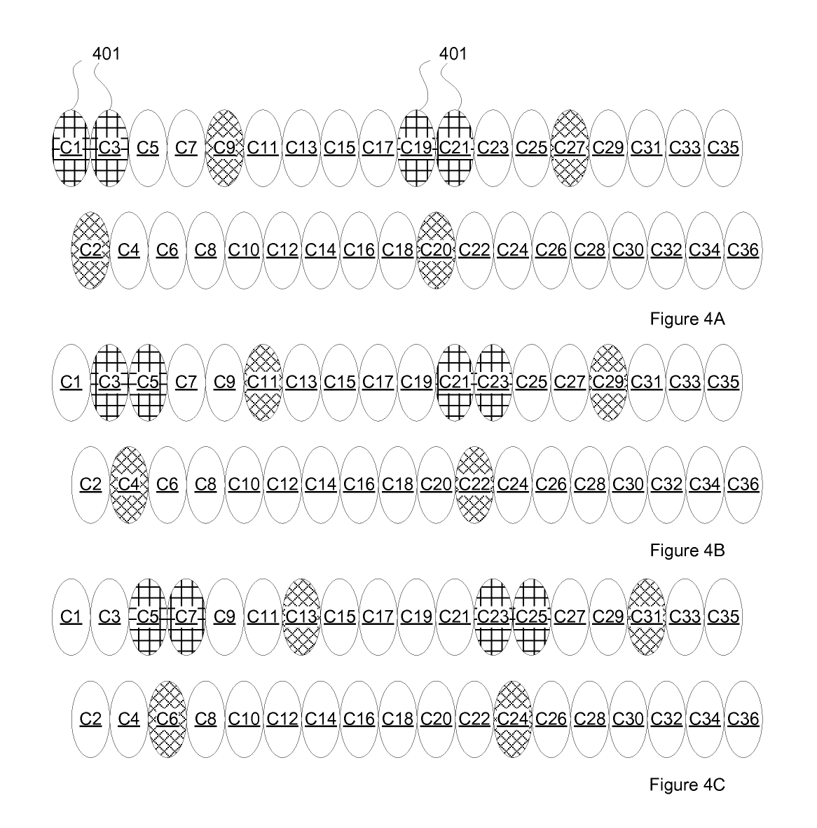

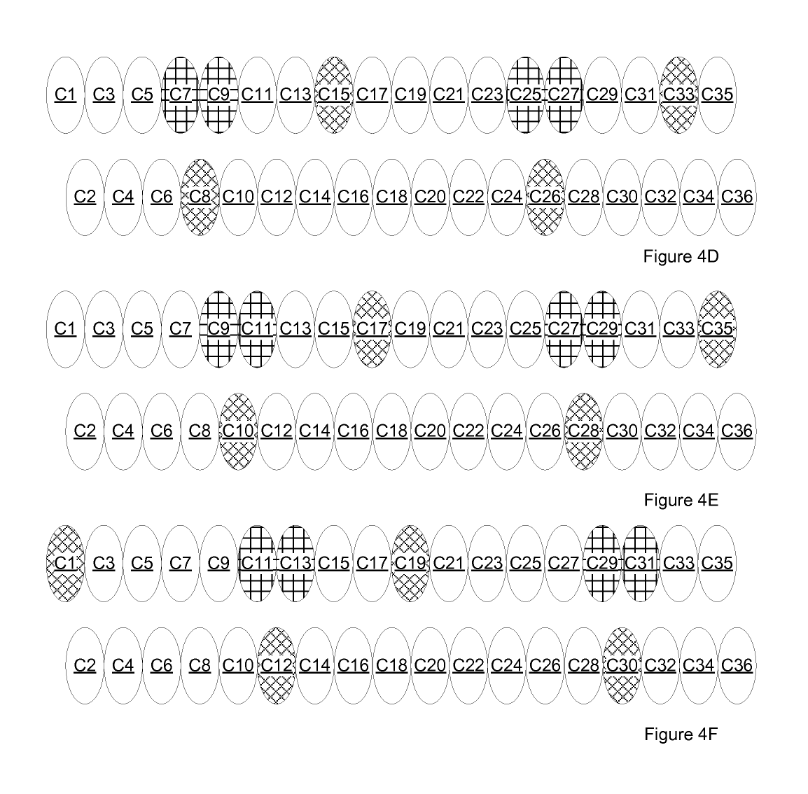

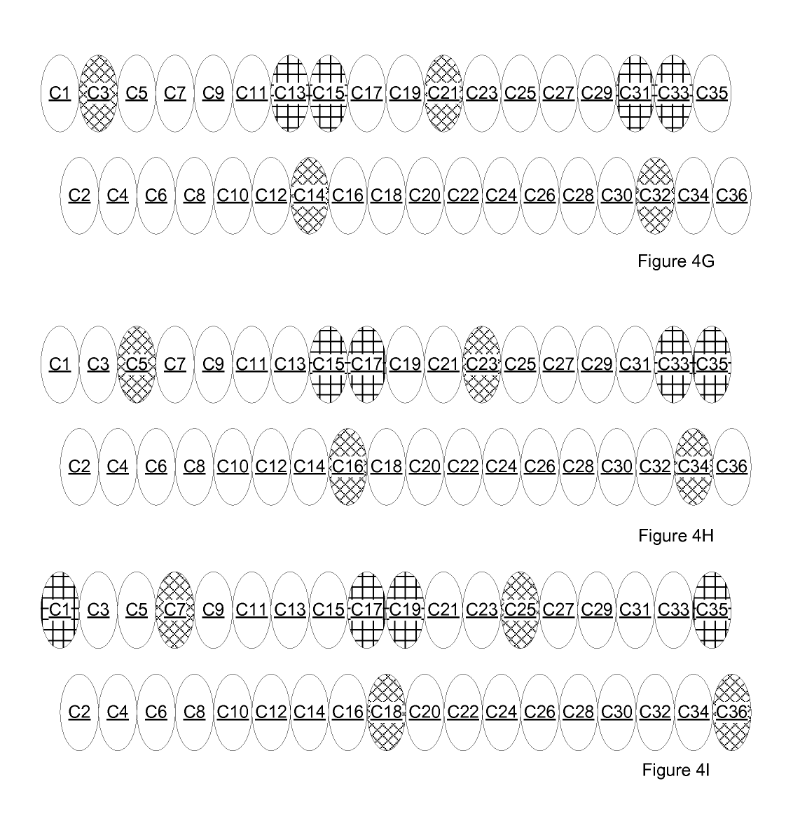

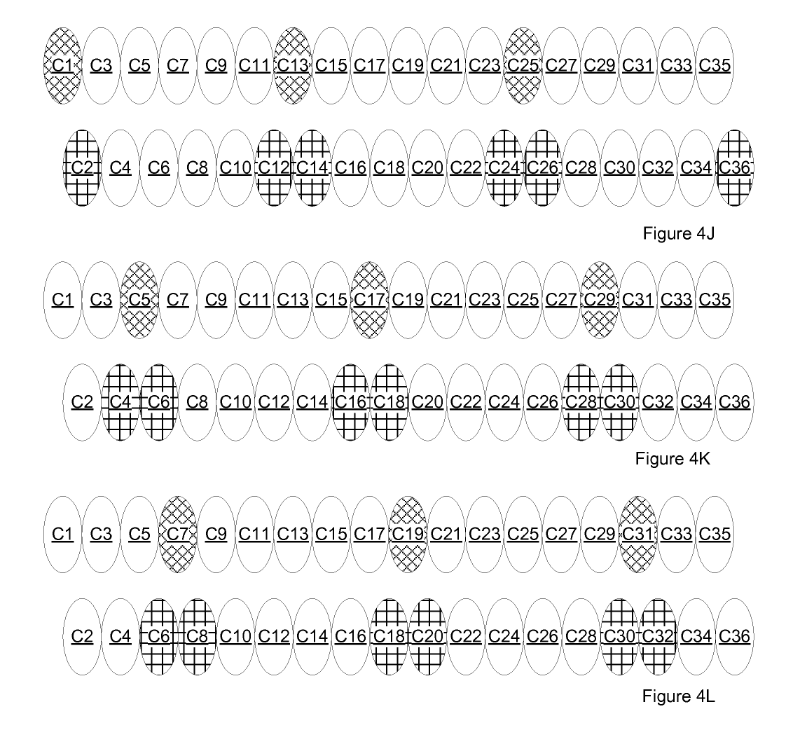

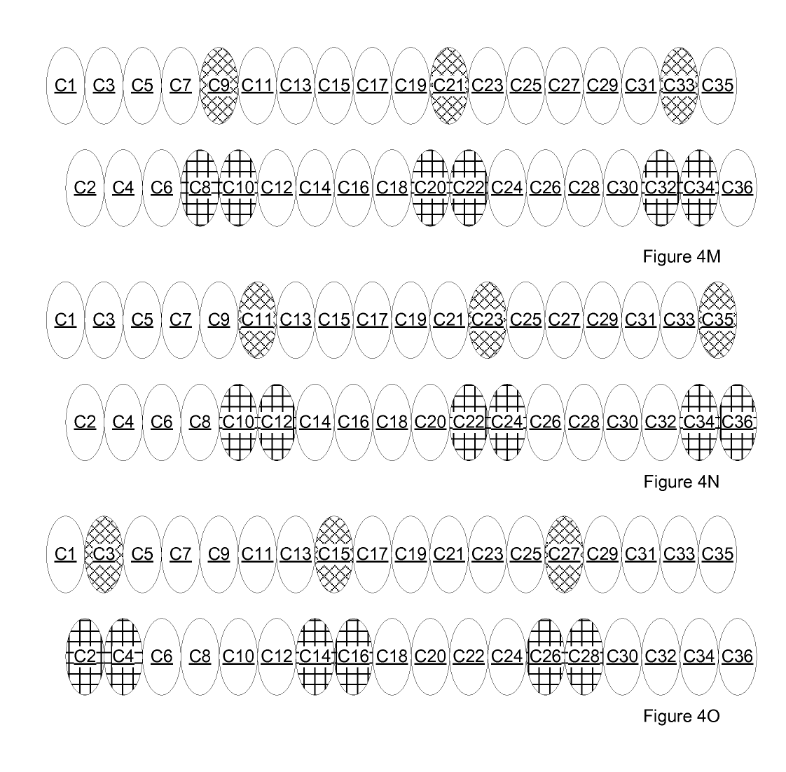

FIG. 4 illustrates an example transmit-receive pattern. The pattern of coil activation for the transmit coils and receiver coils corresponds to a directional probe. The probe is therefore adapted to characterize the orientation of the flaws. During the timeslot shown in FIG. 4A, coils C1, C3, C19 and C21 are used to emit the magnetic field. These coils can be referred to as driver coils, transmit coils 401 or coils excited to transmit/emit. The magnetic fields produced by the transmit coils 401 induce eddy current in the part to be tested/inspected. The induced eddy current is in turn affected by the structure of the part to be tested, especially if the structure of the part contains flaws. The induced eddy current emits some magnetic field as well.

Coil C9 is used as a receive coil to convert some of the magnetic field emitted by the eddy current into voltage. Coil C9 can be referred to as a receive coil, a read out coil or a coil in receive mode. In the present case, the signal from coil C9 is sensitive to transversal and volumetric flaws located in the area of coils C5 and C7 because it is sensitive to the eddy current induced by the transmit coils C1 and C3. It is almost insensitive to the eddy current induced by coils C19 and C21 because they are too far from receive coil C9. The impact of coils C19 and C21 is relatively small in contrast to that of coils C1 and C3. For some applications, the impact of coils C19 and C21 on coil C9 is unacceptable.

Receive coil C27 is used as a receiver to convert some of the magnetic field emitted by the eddy current into a voltage reading. In this case, the signal from coil C27 is sensitive to transversal and volumetric flaws located in the area of coils C23 and C25 because it is sensitive to the eddy current induced by the transmit coils C19 and C21.

Coil C2 used as a receiver converts some of the magnetic field emitted by the eddy current into voltage. In this case, the signal from coil C2 is sensitive to longitudinal and volumetric flaws located in the area between coils C1, C2 and C3, namely at the center of the free area between coils C1, C2 and C3, because it is sensitive to the eddy current induced by transmit coils C1 and C2. It is almost insensitive to the eddy current induced by coils C19 and C21 because they are too far from receive coil C2.

Coil C20 is used as receiver to convert some of the magnetic field emitted by the eddy current into voltage. In this case, the signal from coil C20 is sensitive to longitudinal and volumetric flaws located in the area between coils C19, C20 and C21, namely at the center of the free area between coils C19, C20 and C21 because it is sensitive to the eddy current induced by transmit coils C19 and C20. It is almost insensitive to the eddy current induced by coils C1 and C3 because they are too far from receive coil C20.

In FIG. 4A, the transmit coils 401 are excited in pairs of adjacent coils. This is referred to as a double-driver mode. Pair 1 includes coils C1 and C3 and Pair 2 includes coils C19 and C21. The receive coils C2 and C9 are provided as single and separate coils.

In FIG. 4A, there are two poles of excitation. Pole 1 corresponds to Driver Pair 1 with its receive coils C2, C9 and Pole 2 corresponds to Driver Pair 2 with its receive coils C20, C27.

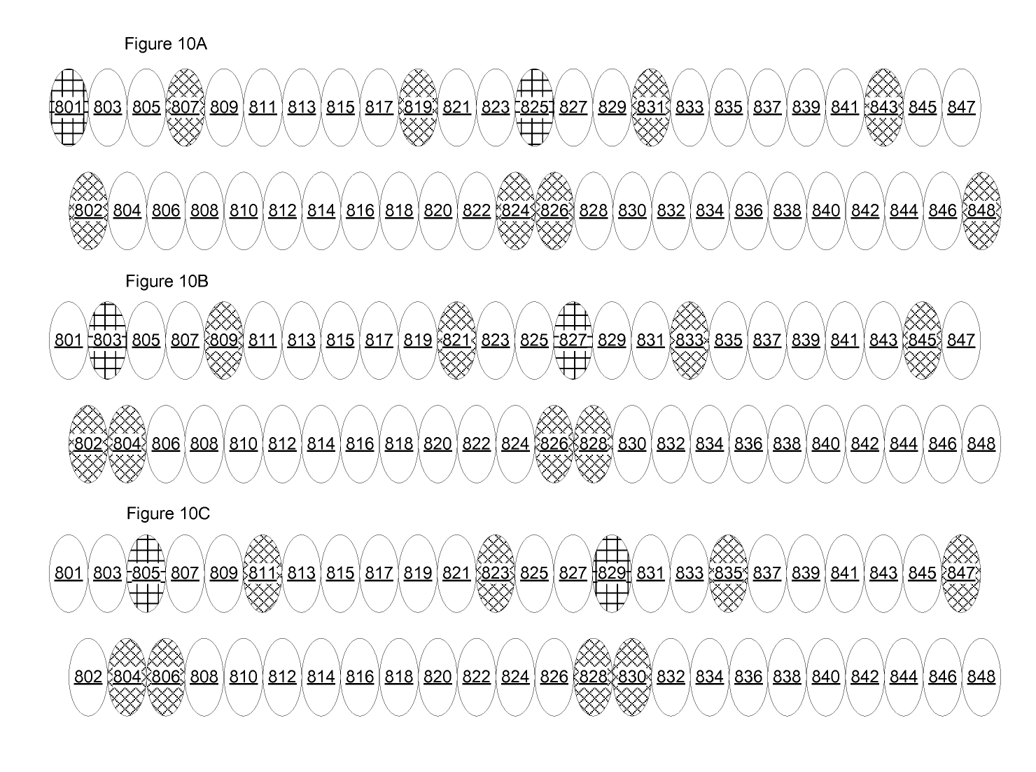

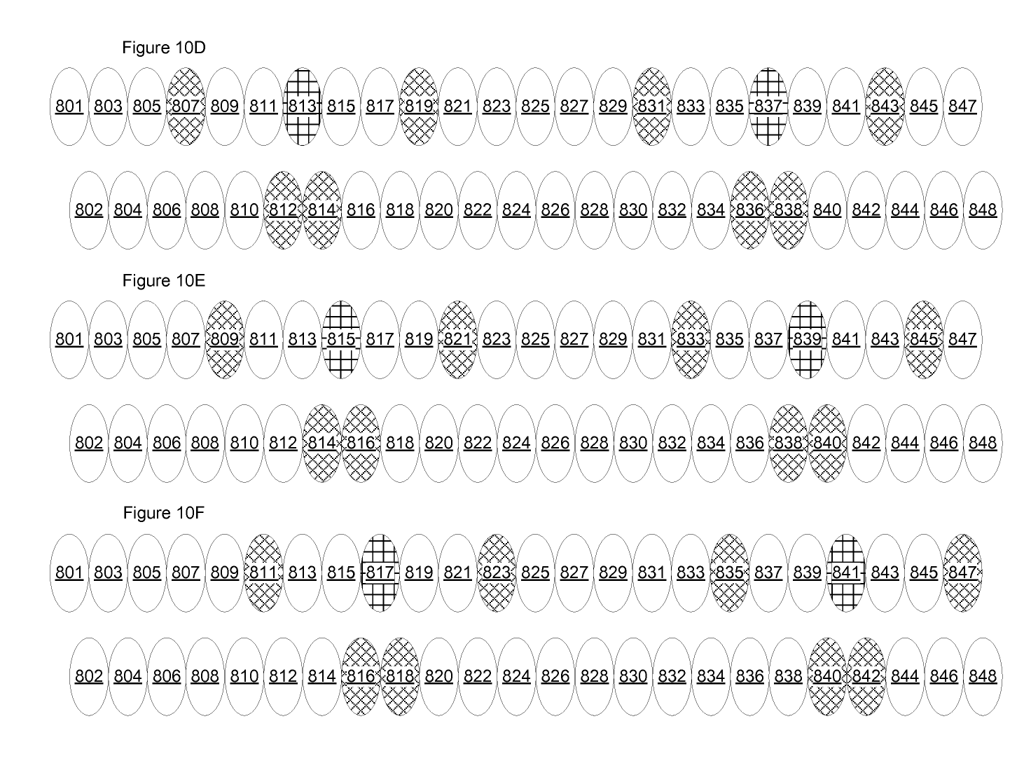

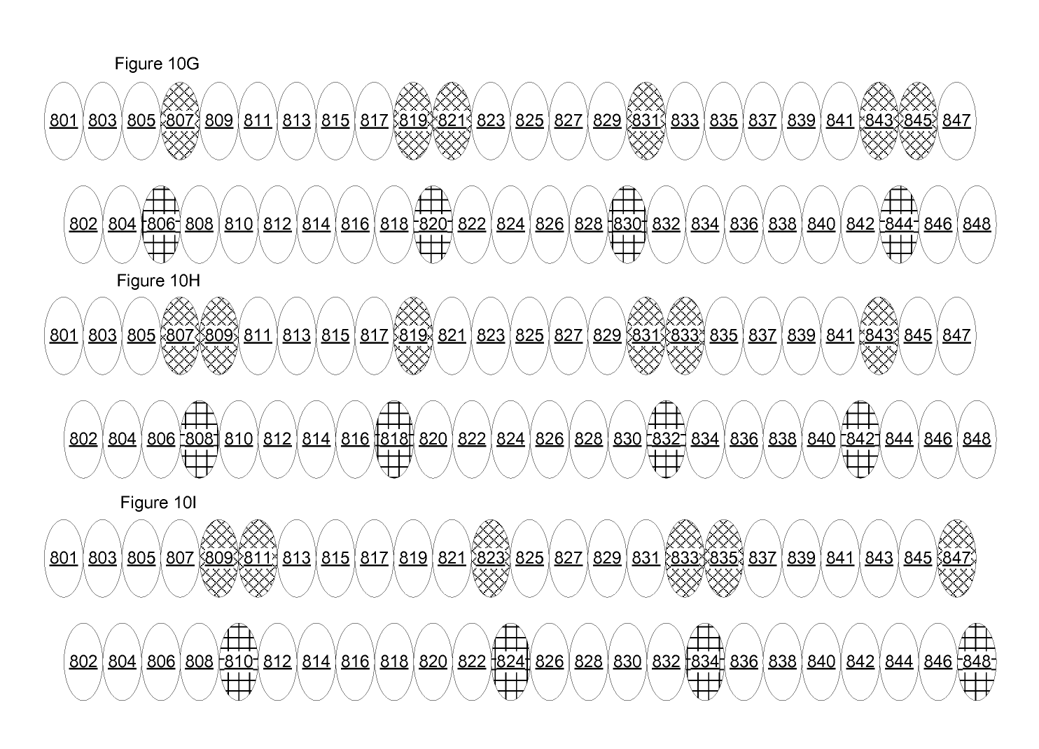

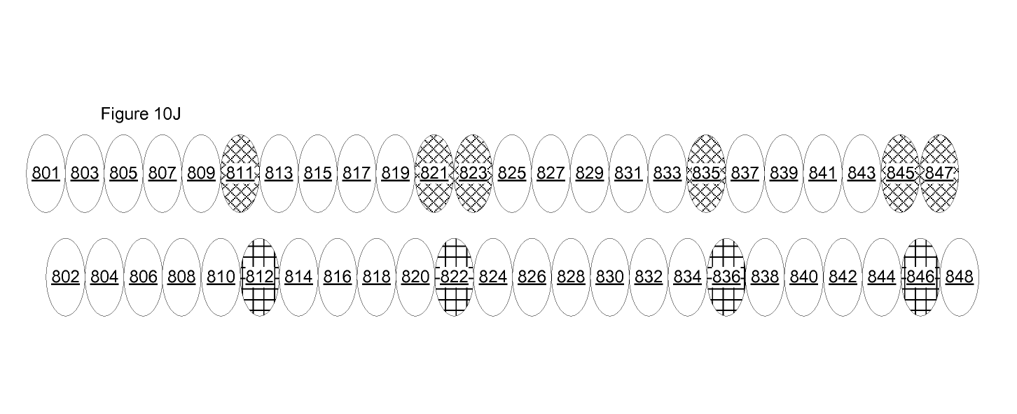

The person skilled in the art will be able to determine the distance between poles of excitation sufficient to make the potential interference between the poles negligible or acceptable. It has been found, in the examples shown herein, that a distance of 4 high density coils between poles of excitation is sufficient. Alternatively, in the example configuration of FIG. 10, the number of unused coils between the receive coils of adjacent poles of excitation is higher.

FIG. 4A to FIG. 4O show 15 timeslots of an example time-multiplexed transmit/receive sequence in double-driver mode. Multiplexing allows a full coverage to inspect the surface of the part located under the coil area in less timeslots. As can be seen in FIG. 4J to FIG. 40, more than two poles of excitation can be provided, in this case, three poles are provided.

Having a plurality of poles of excitation is not mandatory. A sequence could include only one pole of excitation per timeslot. In that case, the sequence would typically require more timeslots to achieve a full inspection. This would require a longer inspection time at each scan location.

A basic probe design includes one conductor for each coil. To reduce the effect of interference and cross-talk (noise), a coaxial cable, a twisted pair cable or a shielded conductor is used instead of a plain wire conductor. Micro-coax cables, such as those used in medical applications, can be used if diameter size is an issue. The conductors for each coil are bundled in a conduit which typically has a substantial length to connect the probe to the test equipment. If the part to be inspected is a tube with curves, bends or U-turns, the conduit should be flexible enough to allow displacement within the tube. If the conduit contains an important number of conductors, it can be too rigid to follow the tube shape. In order to facilitate manufacturing of a flexible conduit, it is possible to provide at least one multiplexer unit in the probe body. A single conductor can then carry the signal for a plurality of coils and via the multiplexer unit, control the appropriate coil usage for the current timeslot. These multiplexer units are typically synchronized to ensure that switching of the mode of the coils is done at the appropriate time for each timeslot. The multiplexer unit can also be provided on the printed circuit board on which coils may be supported.

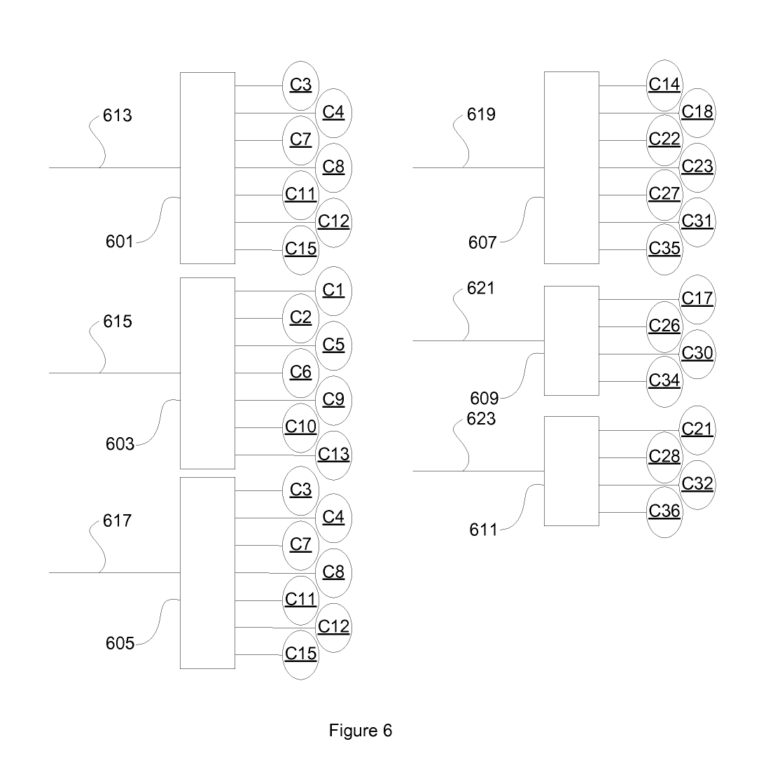

FIG. 6 shows example connections of the coils C1 to C36 with conductors 613, 615, 617, 619, 621 and 623 via multiplexers 601, 603, 605, 607, 609 and 611 to reduce a number of conductors required to control the coils for the sequence of FIG. 4. The conductors in this example bring the AC signal for the transmit coils.

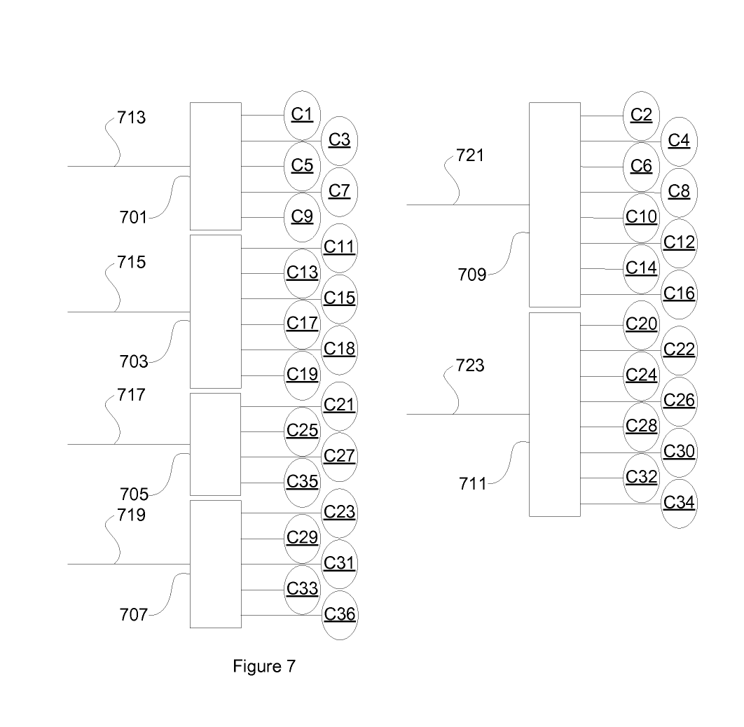

FIG. 7 shows example connections of the coils C1 to C36 with conductors 713, 715, 717, 719, 721 and 723 via multiplexers to reduce a number of conductors required to control the coils for the sequence of FIG. 4. The conductors in this example bring the receive coil signals to the electronic equipment.

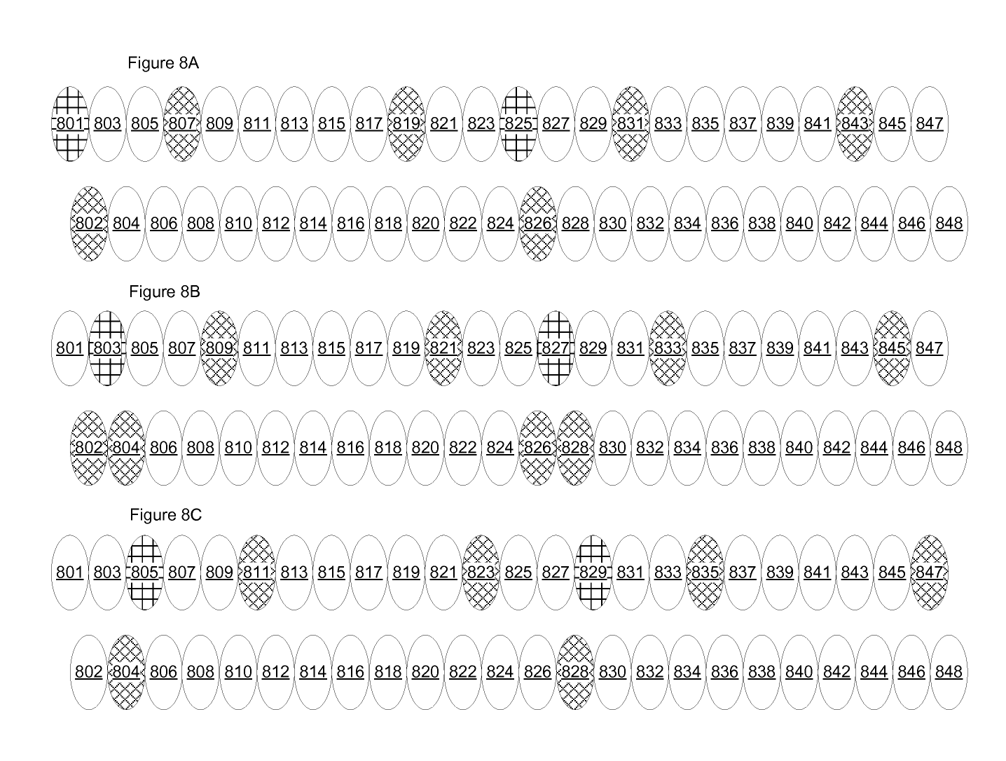

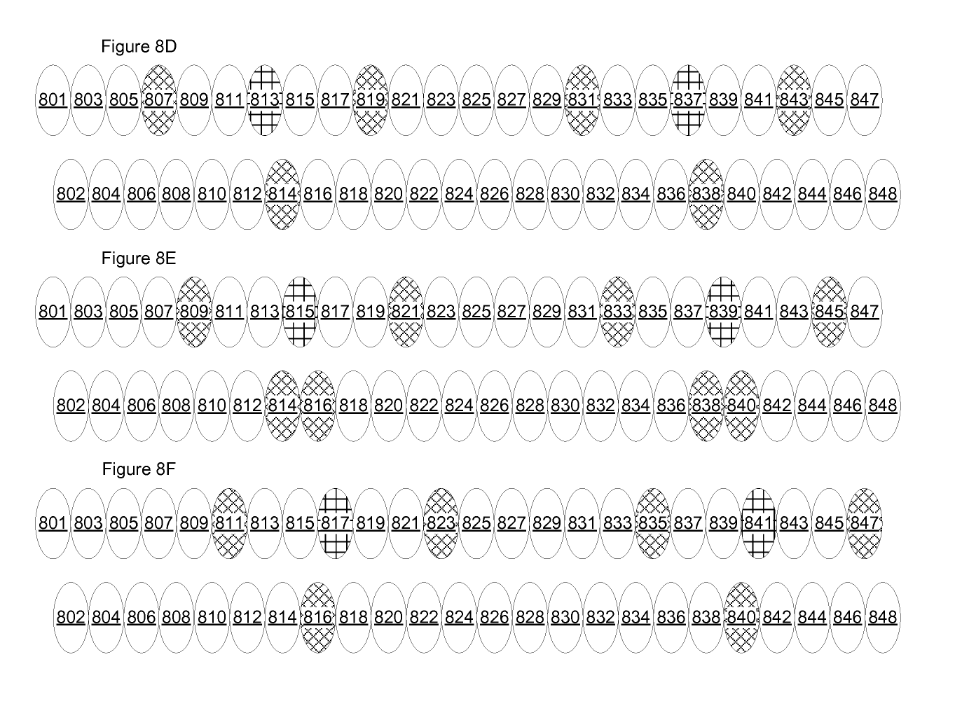

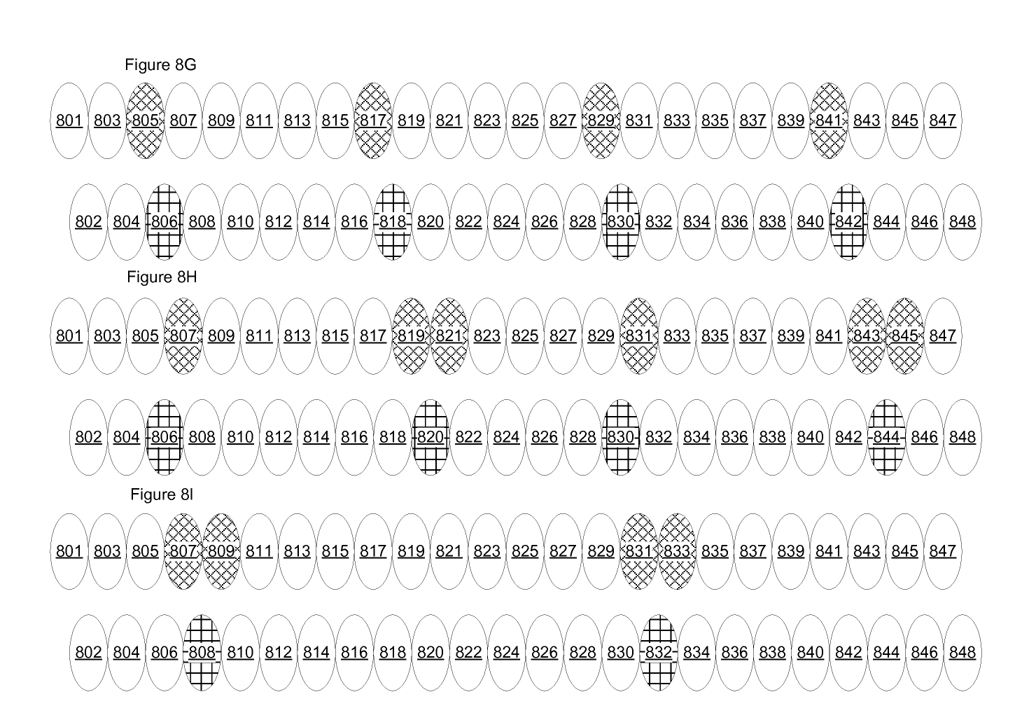

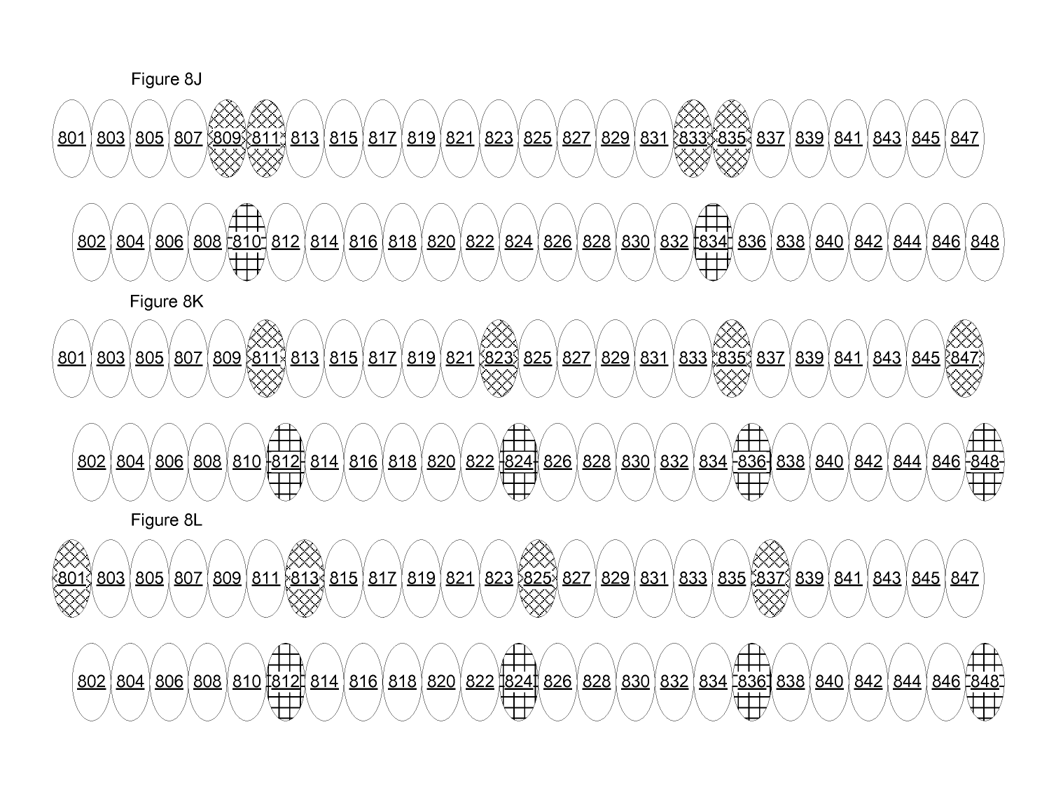

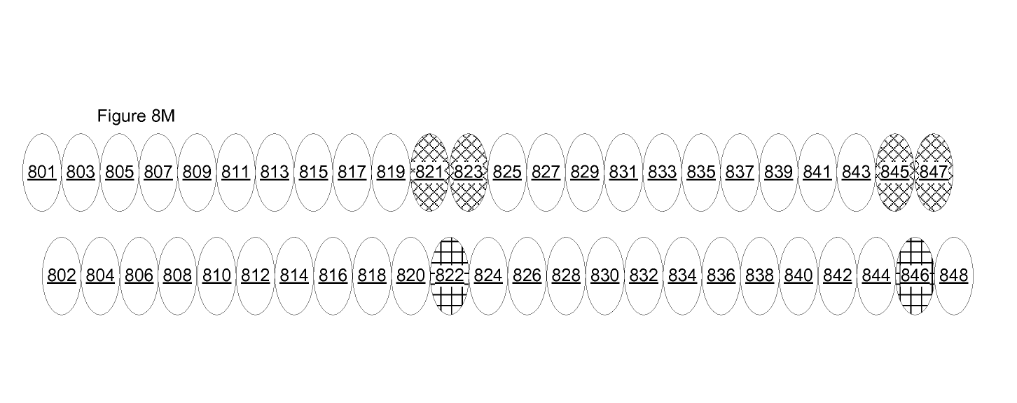

FIG. 8 includes FIG. 8A to FIG. 8M which show 13 timeslots of a time-multiplexed transmit/receive sequence for an example probe having two rows of 24 coils 801 to 848. In FIG. 8, the transmit coils are provided as single transmit, spaced apart coils. This is referred to as a single-driver mode. The receiver coils can be provided in pairs or as single and separate coils.

In FIG. 8, there are two or four poles of excitation depending on the timeslot. In FIGS. 8A to 8F, 8J, 8M, there are two poles of excitation. In FIGS. 8G to 81, 8K, 8L, there are four poles of excitation.

In FIG. 8, some transmit coils have three or four accompanying receive coils, two in the transversal axis and one or two on the other row of coils. The pole of excitation therefore includes 4 or 5 coils. Coil 827 in FIG. 8B is a transmit coil accompanied by receive coils 821, 833, 826 and 828. Some transmit coils also have a single receive coils. Transmit coil 801 in FIG. 8L has a single receive coil 848.

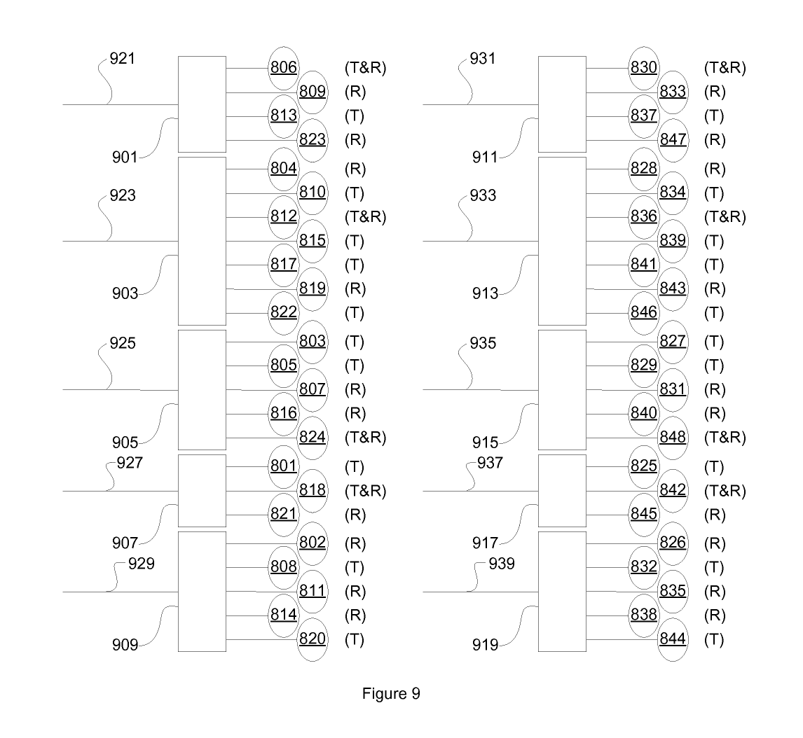

FIG. 9 shows example connections of the coils 801 to 848 with conductors 921, 923, 925, 927, 929, 931, 933, 935, 937 and 939 via multiplexers 901, 903, 905, 907, 909, 911, 913, 915, 917 and 919 to reduce a number of conductors required to control the coils for the sequence of FIG. 8.

FIG. 10 includes FIG. 10A to FIG. 10J which show 10 timeslots of a time-multiplexed excitation/receive sequence for an example probe having two rows of 24 coils 801 to 848.

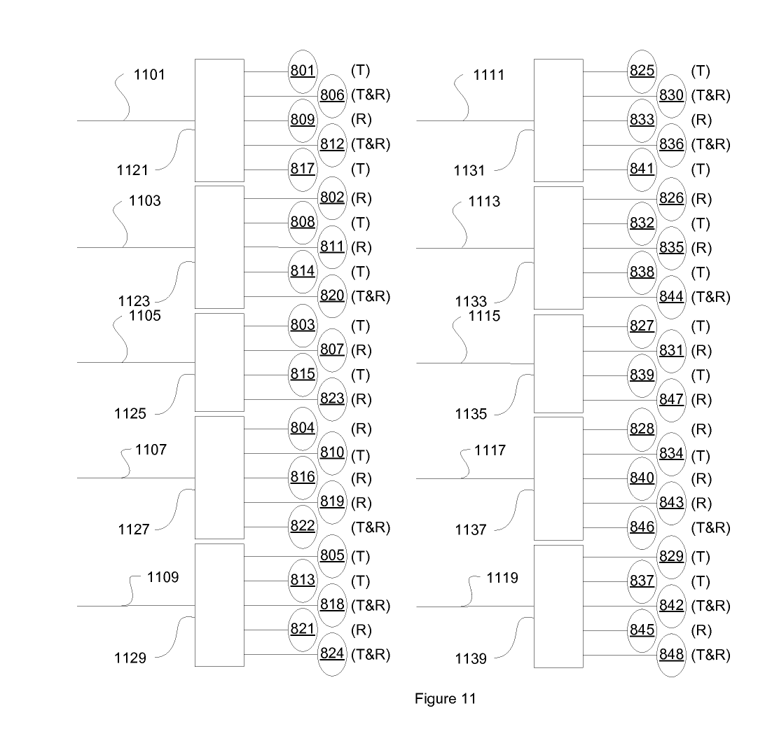

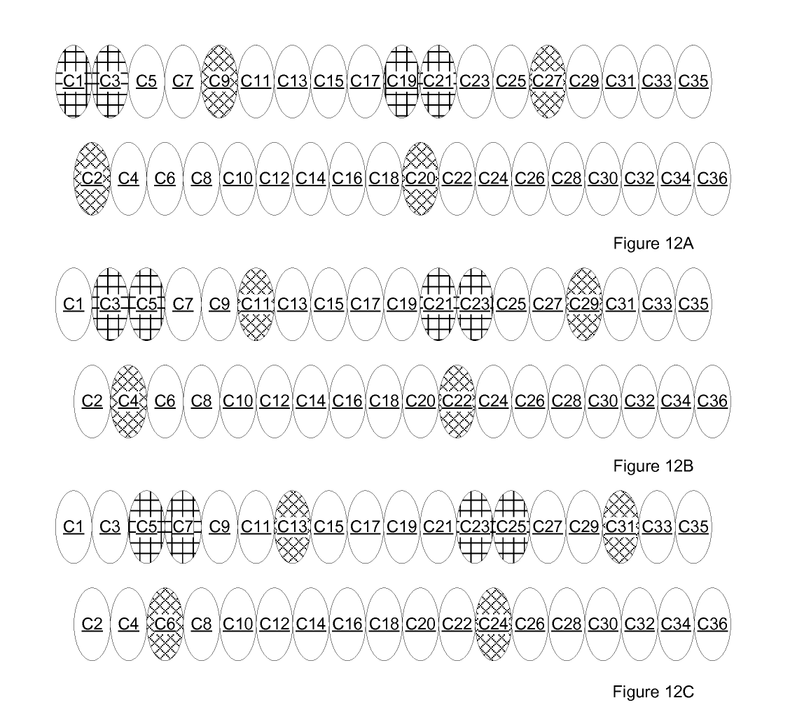

FIG. 11 shows example connections of the coils 801 to 848 with conductors 1101, 1103, 1105, 1107, 1109, 1111, 1113, 1115, 1117 and 1119 via multiplexers 1121, 1123, 1125, 1127, 1129, 1131, 1133, 1135, 1137 and 1139 to reduce a number of conductors required to control the coils for the sequence of FIG. 10.

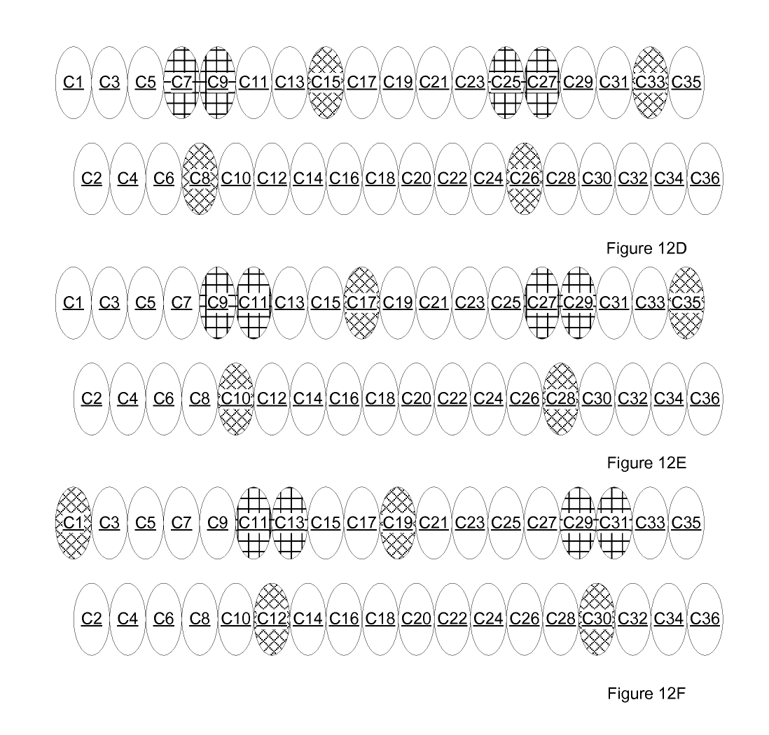

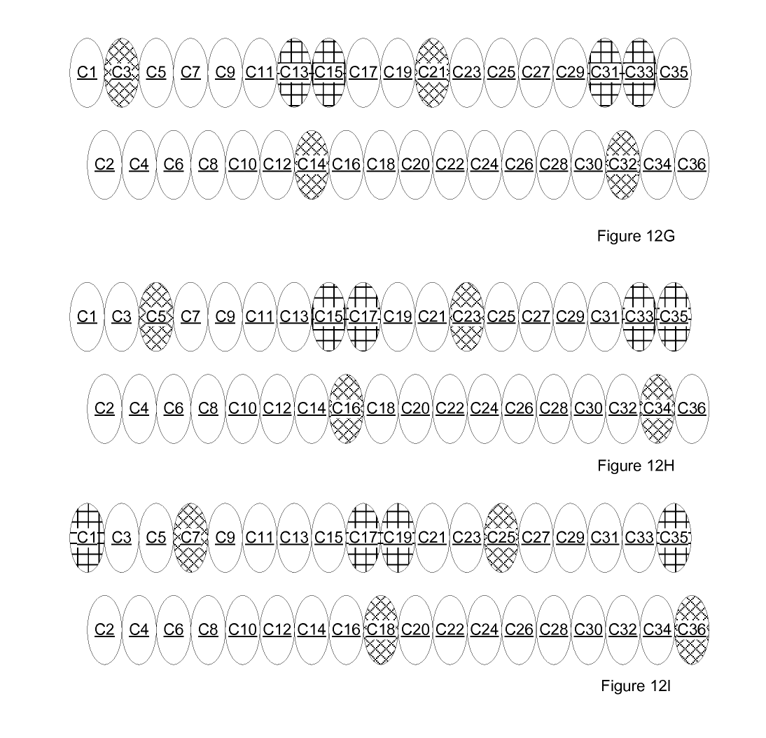

FIG. 12 includes FIG. 12A to FIG. 121 which show 9-timeslot of a time-multiplexed transmit/receive sequence for an example probe having two rows of 18 coils.

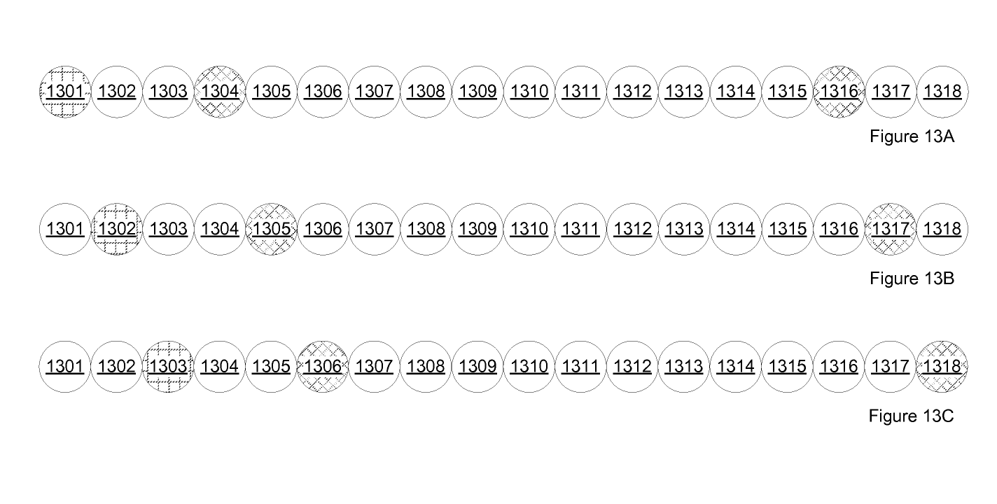

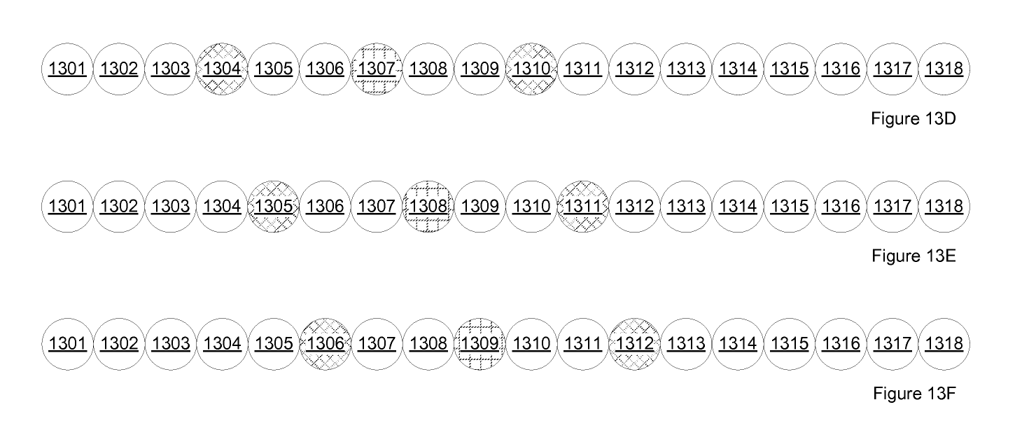

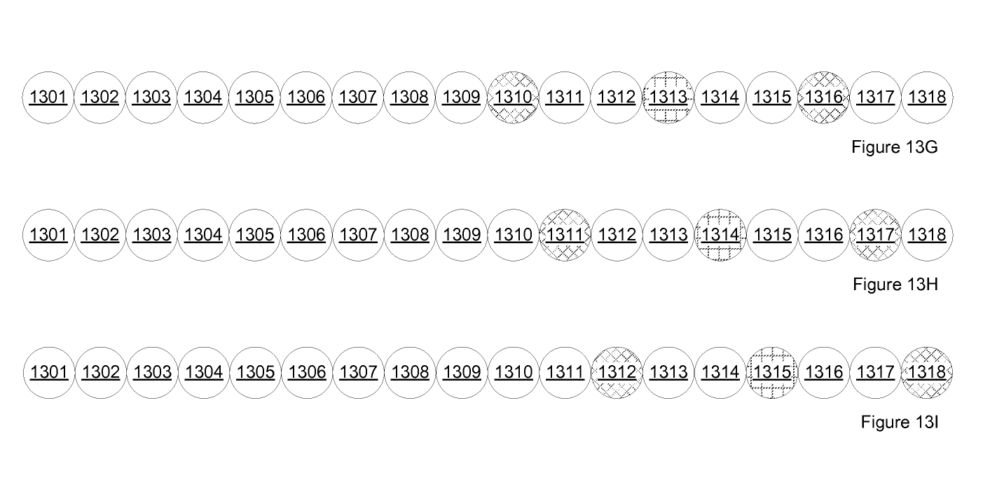

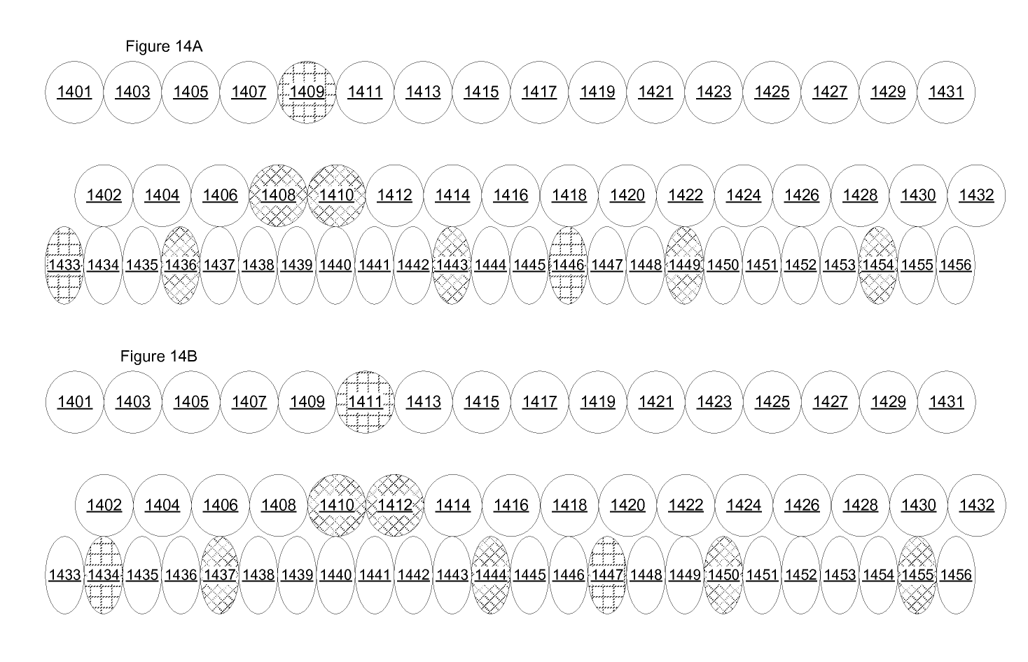

FIG. 13 includes FIG. 13A to FIG. 131 which show 9 timeslots of a time-multiplexed transmit/receive sequence for an example probe with an array of 18 circular coils 1301 to 1318 on one single row. In this example, the coils are mounted on a cylindrical probe body and the row has a circumference of 360°. Coil 1318 is therefore adjacent to coil 1301. This probe is mainly sensitive to circumferential and volumetric flaws. The receive coils are most sensitive to the flaws located in the middle of the distance between transmit and receive coils. For example, in FIG. 13A, coil 1301 is used as a transmit coil and coils 1316 and 1304 are used as receive coils. In this case, receive coil 1316 has a maximum sensitivity for flaws located between coils 1317 and 1318. Similarly, receive coil 1304 has a maximum sensitivity for flaws between coils 1302 and 1303. In this example, each figure has 2 zones of sensitivity for each timeslot. After the 9-timeslot sequence, a total of 18 zones of sensitivity have been triggered, corresponding to the 18 spaces between coils of the array. There are two coils in an inactive mode between the coil in transmit mode and the coil in receive mode for each pole of excitation.

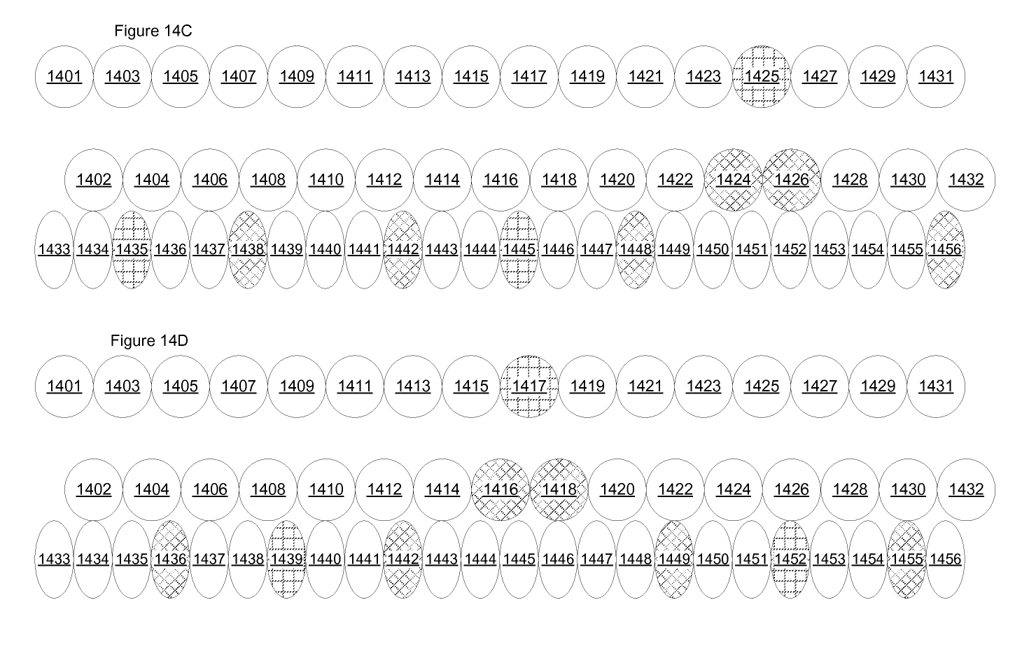

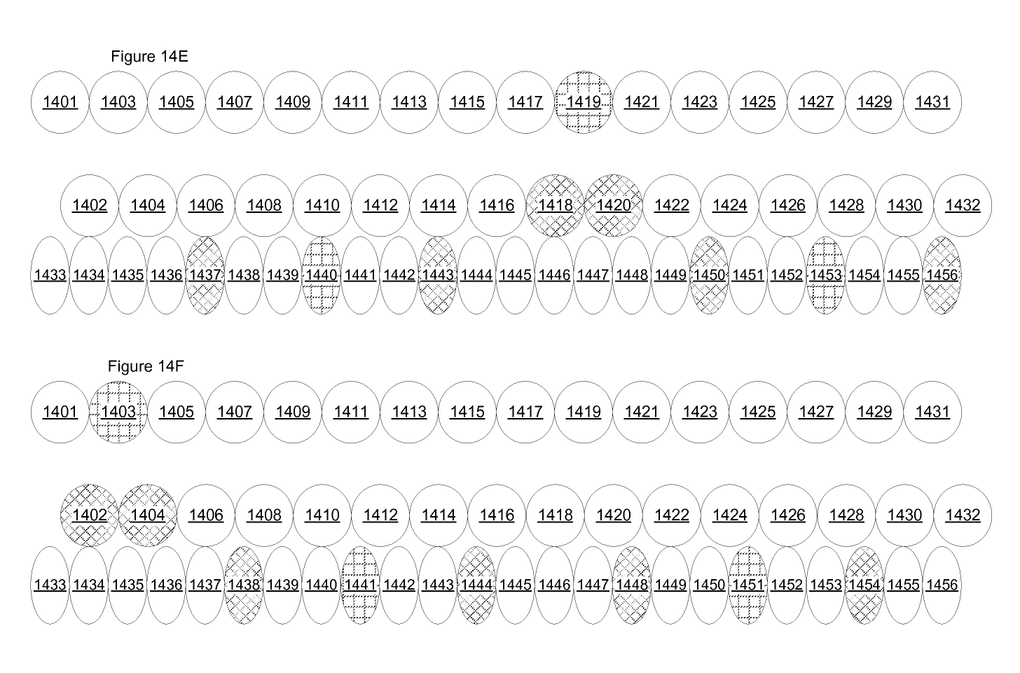

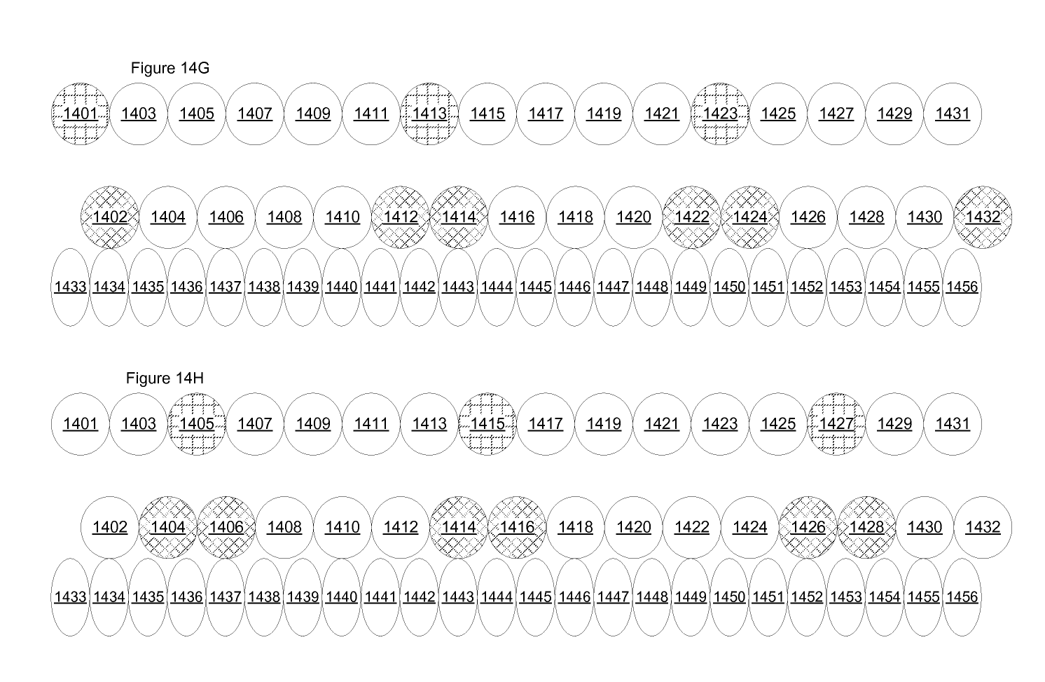

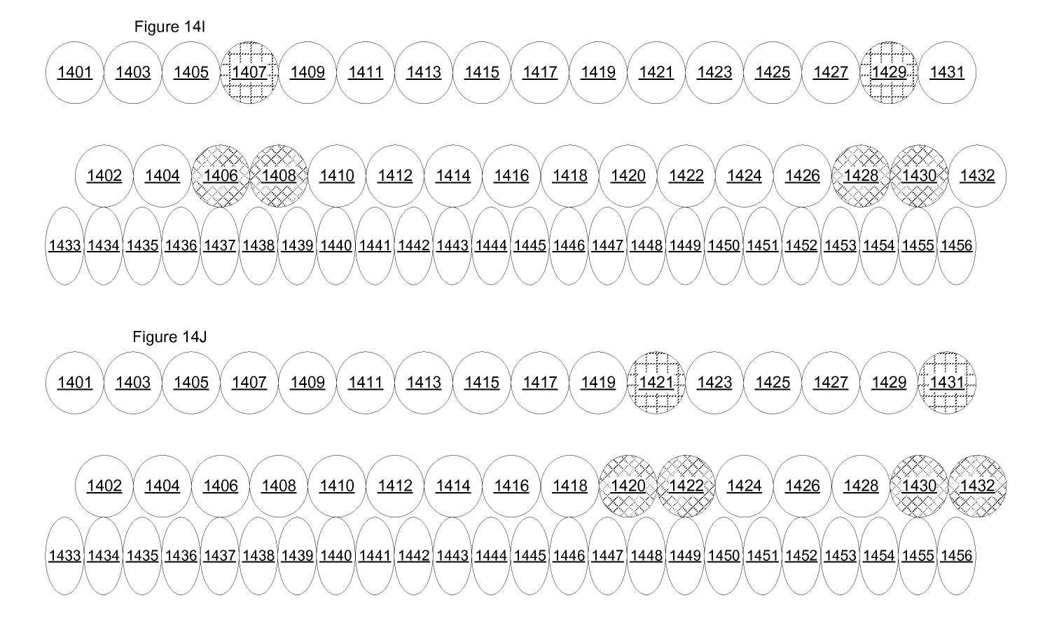

FIG. 14 includes FIG. 14A to FIG. 14J which show 10 timeslots of a time-multiplexed transmit/receive sequence for an example probe having two rows of 16 circular coils and one row of 24 high density coils. The row of high density coils is used to detect and characterize volumetric flaws and circumferentially oriented flaws. The maximum sensitivity is at the middle of the distance between the receive coil and the corresponding transmit coil. In this example, there are a total of 24 zones of sensitivity equally spaced in the circumferential direction. The 2 rows of circular coils are used to detect and characterize volumetric flaws and axially oriented flaws. In this case, 32 zones of sensitivity are equally spaced in the circumferential direction. In this case, during design of the probe, it was determined that high density coils were not necessary on the 2 rows of circular coils because 32 zones of sensitivity were determined to be enough for the application.

FIG. 15 shows example connections of the coils 1401 to 1456 with conductors 1501, 1503, 1505, 1507, 1509, 1511, 1513, 1515 and 1517 via multiplexers 1519, 1521, 1523, 1525, 1527, 1529 1531, 1533 and 1535 to reduce a number of conductors required to control the coils for the sequence of FIG. 14, via optional amplifiers 1537, 1539, 1541, 1543, 1545, 1547, 1549, 1551 and 1553 used to increase the signal from the receive coils and via single pole, double throw switches 1555, 1557, 1559, 1561, 1563, 1565, 1567, 1569 and 1571. Those amplifiers contribute to improve the probe sensitivity and signal to electronic noise ratio. In T position, the conductor brings the AC signal to the multiplexer to the transmit coil. In R position, the receive coil signal passes to the multiplexer, then to the amplifier and to the conductor through the switch.

As will be readily understood, it would be possible to replace any, some or all of the receive coils by Hall effect sensors and/or magnetoresistance sensors such as Giant

MagnetoResistive (GMR), Tunnel MagnetoResistive (TMR), Colossal MagnetoResistive (CMR) and Anisotropic MagnetoResistive (AMR) sensors. Furthermore, other types of sensors could be provided with the array of high density coils to measure additional or redundant characteristics of the part to be inspected. Such measures can serve to output a more complete or a validated characterization of the part to be inspected. Such other sensors include basic eddy current tube inspection coils.

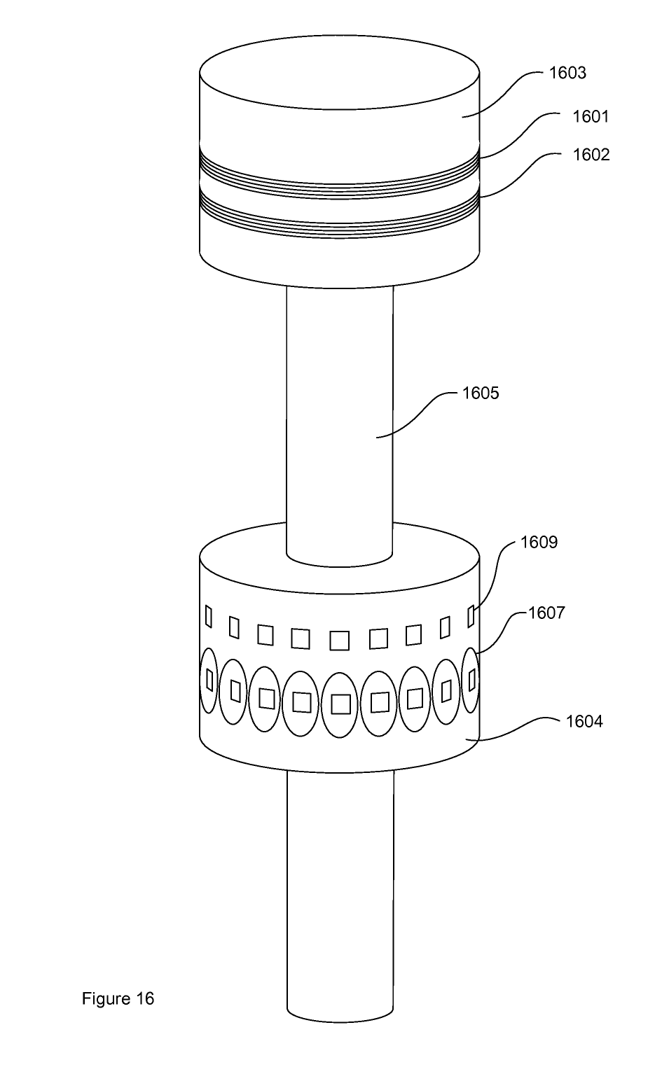

FIG. 16 is an example probe for tubing inspection having circular coils 1601 and 1602 and a row of high density transmit coils 1607 with 2 rows of magneto-resistive or Hall effect sensors. The circular coils 1601 and 1602 are two circumferentially winded coils on the surface of the probe which are typically connected in a bridge of impedance. The circular coils may be provided on an independent body 1603 which is connected to the coil array body 1604 with a flexible conduit 1605. Providing the circular coils and the high density coil array on independent bodies 1603 and 1604 connected via a flexible conduit 1605 facilitates displacement of the probe within a tube having elbows or U-bends. The circular coils 1601 and 1602 could also be provided on the same body as the array of high density coils.

This example probe has a row of 18 identical high density coils 1607. The high density coils are circumferentially located on a same row. Each coil is separated from its adjacent coils by 20 degrees (360 degrees/18 coils). There are two rows of 18 magneto-resistive or Hall effect sensors 1609.

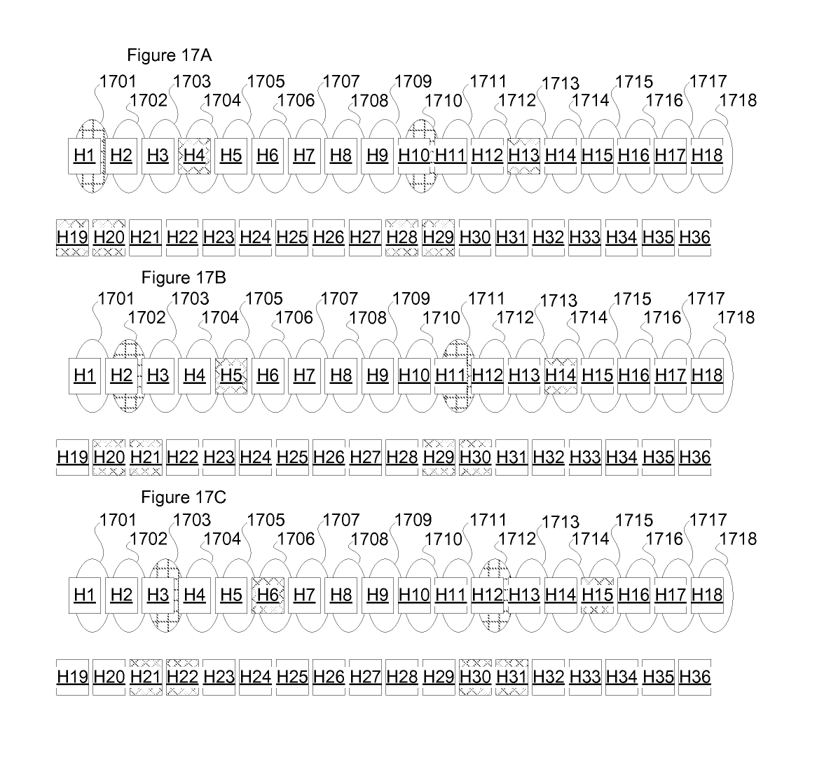

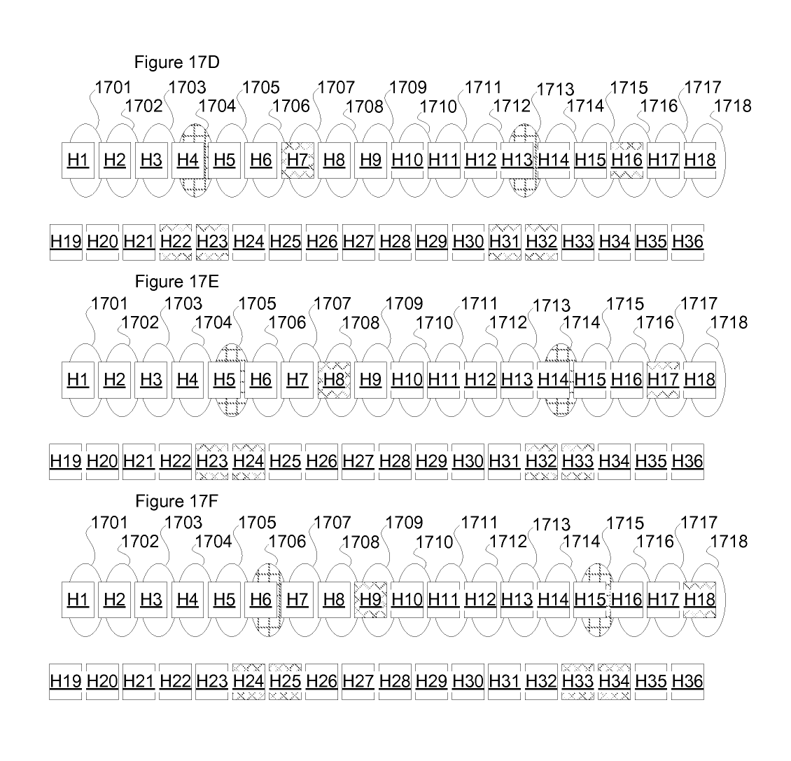

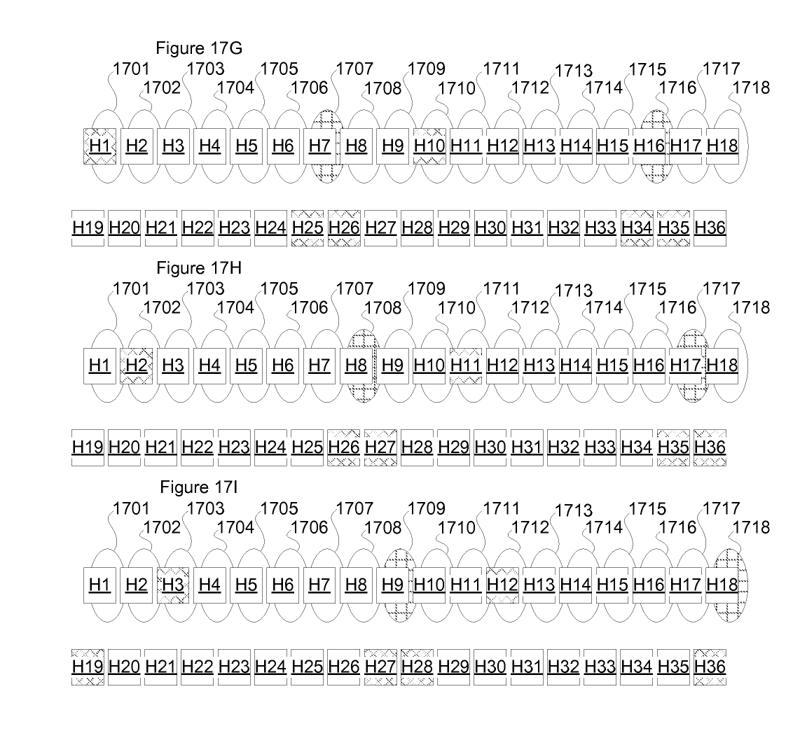

FIG. 17 includes FIG. 17A to FIG. 171 which show 9 timeslots of a time-multiplexed transmit/receive sequence for the example probe shown in FIG. 16. Timeslot 10 is not shown in FIG. 17 but is reserved for the conventional eddy current tube inspection circular coils read out step.

For timeslot 1 to 9 (FIG. 17A to FIG. 171), there are two poles of excitation. For example, in the first timeslot, high density coils 1701 and 1710 are excited. The magneto-resistive or Hall effect sensors H4, H19 and H20 are used to receive the magnetic field emitted by the eddy current induced by high density coil 1701. The magneto-resistive or Hall effect sensors H13, H28 and H29 are used to receive the magnetic field emitted by the eddy current induced by high density coil 1710. The first row of magneto-resistive or Hall effect sensors is superposed on the row of high density coils. The circumferential distance between the high density transmit coils and the receive sensors is determined to obtain the optimal signal performance. The high density coils and receive sensors may not be circumferentially aligned. It may be preferable to superpose the receive sensors on the high density coils or superpose the high density coils on the receive sensors.

In one embodiment, a resistive charge can be provided in series with the coils in transmit mode and the AC source to determine an emission voltage. This can be useful in determining an approximate or indirect measure of the impedance of the transmit coil which is affected by the eddy current.

In some embodiments, at least one coil can be reused as both transmit and a receive coil in different timeslots. In other embodiments, there is no reuse of a same coil for a different mode (transmit or receive). Typically, if there is no reuse of a same coil for different modes, more timeslots will be needed in the sequence to complete a full inspection sequence at each location.

In one embodiment, a magnetic saturation circuit made with a permanent magnet or electromagnet can be added to the probe to saturate the part under inspection or magnetic deposit that could be present on the part. This circuit can be useful to reduce the parasitic signal caused by the magnetic permeability variations.

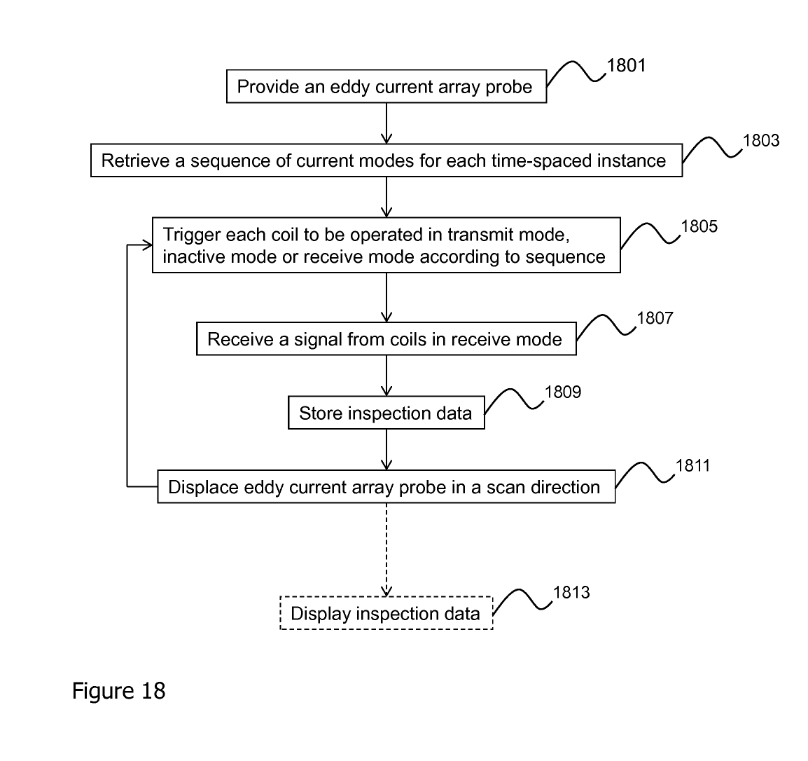

Shown in FIG. 18 is an example method for generating inspection data about an electrically conductive material to be tested using an eddy current array probe. The method includes providing an eddy current array probe in interaction with the electrically conductive material 1801, retrieving a sequence of current modes for each time-spaced instances 1803, triggering each coil to be operated in the mode using the sequence, at each time-spaced instance 1805, receiving a signal from the coils in the receive mode 1807 and storing inspection data using the signal 1809. As will be understood, the eddy current array probe is displaced in a scan direction 1811 and the steps of triggering 1805, receiving 1807, storing 1809 are repeated continuously during the displacing 1811. As such, the steps are not necessarily carried out in sequence but rather can occur continuously, in parallel.

As will be readily understood, the step of storing inspection data using the signal 1809 can comprise a plurality of sub-steps such as filtering, digitalizing, amplifying and demodulating the signal from the receive coil.

The sequence of current modes ensures at least two adjacent coils of the plurality are triggered to be operated in the inactive mode between a coil triggered to be operated in transmit mode and a coil triggered to be operated in receive mode in the linear configuration at each of the time-spaced instances.

In one embodiment, the sequence includes at least one instance in which at least two adjacent coils of the plurality are triggered to be in the transmit mode in the linear configuration.

In one embodiment, the method further comprises multiplexing commands for the triggering.

In one embodiment, the method further comprises displaying the inspection data 1813.

In the examples shown herein, the longitudinal dimension of the elongated shape of the high density coils is shown to be perpendicular to the longitudinal dimension of the row of coils. The coils therefore have an elongated shape in the same axis as the scan direction. As will be readily understood, it would be possible to provide the coils at an angle to the longitudinal dimension of the row. The center of each coil would still be along a single center line for the row but each coil would be tilted to one side. The coils would therefore be provided at an angle to the longitudinal dimension of the row. This angle is a right angle in the examples shown herein.

As will be readily understood, in the case where the surface to be inspected is a pipe, if the coils are provided on a plate, the plate will need to have a somewhat helical scan direction to cover the whole tube. The longitudinal dimension of the row of coils would not be strictly orthogonal to the scan direction.

As will be readily understood, the person skilled in the art will select the appropriate dimensions for the probe, including the diameter for a cylindrical probe body, the length of the body and/or the conduit, etc. and the appropriate minimum, maximum and central frequencies of operation of the probe, the number of coils per row, the number of rows of coils, the type of coils (circular or high density), the type of sensors used to receive the magnetic field, the flexibility of the conduit for the conductors, etc. These design choices will depend partly on the part to be inspected, its material(s), and its dimensions (diameter in the case of a tube, presence of bends, wall thickness, etc.).

The embodiments described above are intended to be exemplary only. The scope of the invention is therefore intended to be limited solely by the appended claims.

1. An eddy current array probe, comprising:
a probe body having a surface, said probe body being adapted to be displaced along a scan direction;
a plurality of coils arranged in a linear configuration on said surface, said coils being adapted to be operated in one mode among a transmit mode, an inactive mode and a receive mode at each of a plurality of time-spaced instances, at least two adjacent coils of said plurality being adapted to be operated in said inactive mode between a coil adapted to be in transmit mode and a coil adapted to be in receive mode in said linear configuration at each of said time-spaced instances;
at least one conductor extending from said probe body;
each coil of said plurality being connected to one of said at least one conductor and a common return path.

2. The eddy current array probe as claimed in claim 1, further comprising a conduit attached to said probe body, said at least one conductor extending within said conduit.

3. The eddy current array probe as claimed in claim 1, wherein said coils have an elongated shape.

4. The eddy current array probe as claimed in claim 3, wherein said elongated shape is an oval shape.

5. The eddy current array probe as claimed in claim 3, wherein a longitudinal dimension of said elongated shape is orthogonal to a longitudinal dimension of said linear configuration.

6. The eddy current array probe as claimed in claim 1, wherein at least two adjacent coils of said plurality are adapted to be operated in said transmit mode in said linear configuration in at least one time-spaced instance of said plurality of time-spaced . instances.

7. The eddy current array probe as claimed in claim 1, wherein said probe body is cylindrical, wherein said linear configuration is a ring-like circumferential configuration on said surface of said probe body, wherein said probe body has a hollow core, wherein said at least one conductor is inserted in said hollow core of said probe body.

8. The eddy current array probe as claimed in of claim 1, wherein said linear configuration includes at least two rows of said coils, said longitudinal dimension of each of said rows being parallel, coils of said rows being in one of an alignment and an offset with coils of an adjacent one of said rows.

9. The eddy current array probe as claimed in claim 1, further comprising a multiplexer in said probe body, said multiplexer being connected between one of said at least one conductor and at least two coils of said plurality of coils.

10. The eddy current array probe as claimed in claim 9, wherein said multiplexer including a multiplexer memory, said multiplexer memory storing a sequence for triggering said coils to be operated in one of said mode at each of said plurality of time-spaced instances.

11. The eddy current array probe as claimed in claim 1, further comprising a plurality of sensors arranged in a sensor linear configuration, said coils being provided on at least one coil row and said sensors being provided on at least one sensor row, said sensors being one of Hall effect sensors and magnetoresistive sensors, said sensor row being one of adjacent to and superposed on said coil row.

12. The eddy current array probe as claimed in claim 1, further comprising an amplifier in said probe body, said amplifier being adapted to amplify a signal from said coil operated in said receive mode.

13. A method for generating inspection data about an electrically conductive material to be tested using an eddy current array probe, comprising:
providing an eddy current array probe in interaction with said electrically conductive material, said eddy current array probe including:
a probe body having a surface, said probe body being adapted to be displaced along a scan direction;
a plurality of coils arranged in a linear configuration on said surface said coils being adapted to be operated in one mode among a transmit mode, an inactive mode and a receive mode at each of a plurality of time-spaced instances, at least two adjacent coils of said plurality being adapted to be operated in said inactive mode between a coil adapted to be in transmit mode and a coil adapted to be in receive mode in said linear configuration at each of said time-spaced instances;
at least one conductor extending from said probe body;
each coil of said plurality being connected to one of said at least one conductor and a common return path;
retrieving a sequence of current modes for each of said time-spaced instances, for each coil of said plurality of coils, said current mode being chosen among said transmit mode, said inactive mode and said receive mode;
triggering each coil of said plurality of coils to be operated in said mode using said sequence, said at least one conductor and a power source, at each of said time-spaced instances;
receiving a signal from said coils in said receive mode using said at least one conductor at each of said time-spaced instances;
storing inspection data using said signal at each of said time-spaced instances;
displacing said eddy current array probe in a scan direction;
repeating said steps of triggering, receiving, storing and displacing;
wherein said sequence of current modes ensures at least two adjacent coils of said plurality are triggered to be operated in said inactive mode between a coil triggered to be operated in transmit mode and a coil triggered to be operated in receive mode in said linear configuration at each of said time-spaced instances.

14. The method as claimed in claim 13, wherein said sequence includes at least one instance in which at least two adjacent coils of said plurality are triggered to be in said transmit mode in said linear configuration.

15. The method as claimed in claim 13, further comprising multiplexing commands for said triggering.

16. The method as claimed in claim 13, further comprising displaying said inspection data.
